(19) United States
(12) Patent Application Publication
(10) Pub. No.: US 2026/0282530 A1
(43) Pub. Date: Sep. 17, 2026

(54) SEMICONDUCTOR DEVICES AND METHODS FOR FORMING THE SAME

(71) Applicant: Taiwan Semiconductor Manufacturing Co., Ltd., Hsinchu (TW)

(72) Inventors: Guan-Lin CHEN, Hsinchu (TW); Wei-Hsuan LIN, Hsinchu (TW); Kuo-Cheng CHIANG, Hsinchu (TW); Shi Ning JU, Hsinchu (TW); Chih-Hao WANG, Hsinchu (TW)

(73) Assignee: Taiwan Semiconductor Manufacturing Co., Ltd., Hsinchu (TW)

(21) Appl. No.: 19/324,861

(22) Filed: Sep. 10, 2025

Related U.S. Application Data
(60) Provisional application No. 63/772,204, filed on Mar. 14, 2025.

(51) Int. Cl. H10D 84/83; H10D 30/00; H10D 30/01; H10D 30/43; H10D 62/10; H10D 62/13; H10D 64/01; H10D 84/01

(52) U.S. Cl. CPC H10D 84/832; H10D 30/014; H10D 30/0191; H10D 30/43; H10D 30/502; H10D 30/503; H10D 62/121; H10D 62/151; H10D 64/017; H10D 84/0135; H10D 84/0144; H10D 84/0147

(57) ABSTRACT

A method for forming a semiconductor device includes forming a fin structure extending along a first direction over a substrate, the fin structure having a height along a second direction transverse the first direction and including a stack portion of alternating channel semiconductor portions and sacrificial material portions and a hard mask portion over the stack portion. The sacrificial material portions include a first sacrificial material portion in contact with the hard mask portion and second sacrificial material portions below the first sacrificial material portion. Next, the first sacrificial material portion and the second sacrificial material portions are laterally recessed, with the first sacrificial material portion being etched to a greater extent than the second sacrificial material portions. After removing the recessed first and sacrificial material portion and sacrificial material portions to form a plurality of channel nanostructures, a gate stack is formed to surround the channel nanostructures.

### PRIORITY CLAIM AND CROSS-REFERENCE

This application claims the benefit of U.S. Provisional Patent Application No. 63/772,204, filed Mar. 14, 2025, which is incorporated by reference herein in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method for fabricating a gate-all-around (GAA) device, in accordance with some embodiments of the present disclosure.

FIGS. 2-18B are cross-sectional views of the GAA device during a fabrication process according to the method of FIG. 1, in accordance with some embodiments of the present disclosure.

FIG. 19 is a flowchart of a method of forming the GAA device, in accordance with alternative embodiments of the present disclosure.

FIGS. 20A-26B are cross-sectional views of the GAA device during a fabrication process according to the method of FIG. 19, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Non-planar transistor architectures, such as nanosheet field-effect transistors (FETs), utilize semiconductor nanosheet channels with gate-all-around (GAA) technologies to enhance device density, power efficiency, and performance compared to fin-type FETs. In a GAA configuration, a nanosheet FET includes a source feature, a drain feature, and vertically stacked and spaced nanosheet channels between the source and drain features. A gate surrounds the nanosheet channels and regulates electron flow through the nanosheet channels between the source and drain features. GAA nanosheet FETs are fabricated by forming alternating layers of channel nanosheets and sacrificial nanosheets. The sacrificial nanosheets are released from the channel nanosheets before the FET device is finalized.

In stacked nanosheet GAA FETs, the nanosheets used for channel formation typically have uniform thickness. However, the top nanosheet often experiences greater junction push than the lower sheets, as the top nanosheet receives more dopants during source/drain implantation to form epitaxy source/drain features. The higher dopant concentration causes the junction to encroach further towards the gate, increasing the effective capacitance (Ceff) between the source/drain features and the gate. The increased Ceff may degrade device performance by increasing parasitic coupling and reducing switching speed.

Embodiments of the present disclosure effectively reduce the Ceff by implementing a thicker topmost sacrificial semiconductor portion relative to the underlying sacrificial semiconductor portion. These sacrificial semiconductor portions are subsequently removed to release the channel nanostructures and are replaced with a metal gate stack. The increased thickness of the topmost sacrificial portion results in a smaller metal gate critical dimension (CD) and a thicker inner spacer at the top of channel nanostructures, both of which help to reduce Ceff between the source/drain features and the metal gate stack. As a result, the performance of the GAA FETs can be improved.

The GAA transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process.

Spacers are formed alongside the patterned sacrificial layer using a self-aligned process. The sacrificial layer is then removed, and the remaining spacers may then be used to pattern the GAA structures.

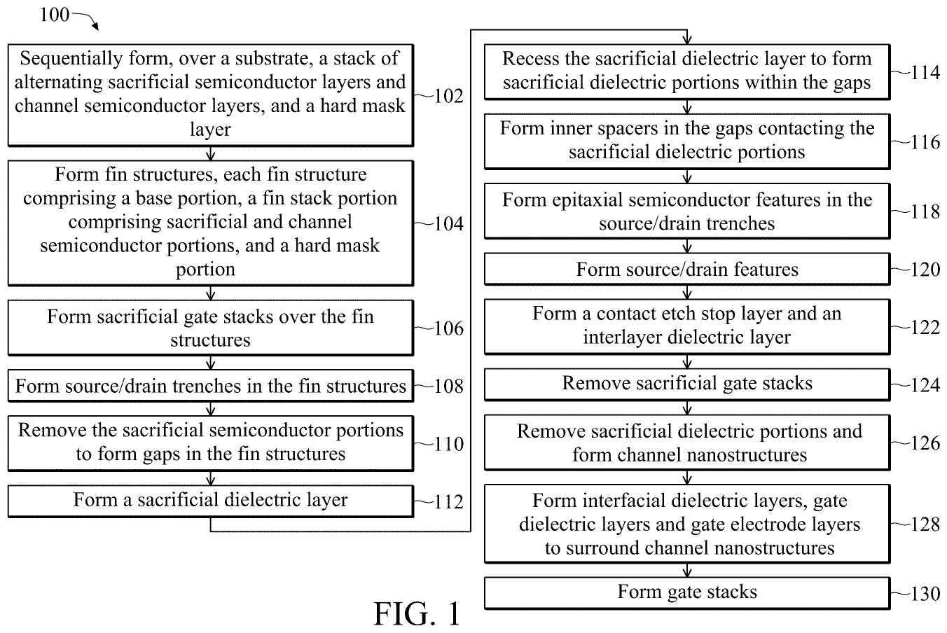

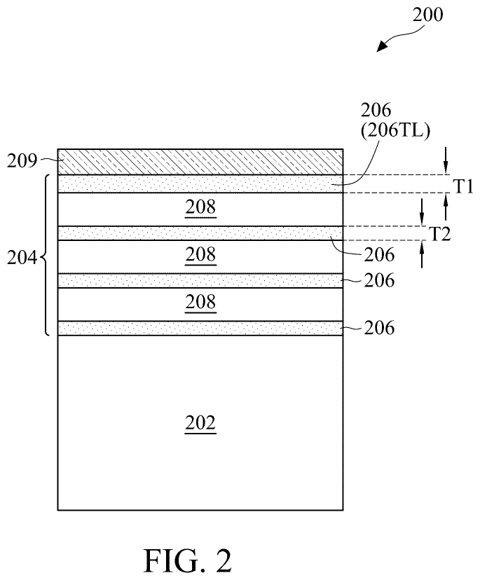

FIG. 1 is a flowchart of a method 100 of forming a GAA device 200, in accordance with some embodiments of the present disclosure. FIGS. 2-18B are various views of the GAA device 200 at various stages of the method 100, in accordance with some embodiments. Some embodiments of method 100 are described below in conjunction with FIGS. 2-18B with reference to the GAA device 200. The method 100 is merely an example and is not intended to limit the present disclosure beyond what is explicitly recited in the claims. Additional operations can be provided before, during, and after the method 100, and some operations described can be replaced, eliminated, or moved around for additional embodiments of the method.

Referring to FIGS. 1 and 2, the method 100 includes operation 102, where an initial structure of the GAA device 200 is provided. The initial structure includes a substrate 202, a stack 204 of alternating epitaxial semiconductor layers over the substrate 202, and a hard mask layer 209 over the stack 204. FIG. 2 is a cross-sectional view of the GAA device 200 after forming the stack 204 of the alternating epitaxial semiconductor layers over the substrate 202 followed by forming the hard mask layer 209 over the stack 204.

The substrate 202 can be any suitable substrate and can be processed with various features. In some embodiments, the substrate 202 may be a semiconductor substrate, such as a silicon substrate. In some embodiments, the substrate 202 may include various layers, including conductive or insulating layers formed on a semiconductor substrate. The substrate 202 may include various doping configurations. For example, different doping profiles (e.g., n wells, p wells) may be formed on the substrate 202 in regions designed for different device types (e.g., n-type FETs, p-type FETs). Suitable doping may include ion implantation of dopants and/or diffusion processes. The substrate 202 typically has isolation features (e.g., shallow trench isolation (STI) features) interposing the regions providing different device types. The substrate 202 may include other semiconductors such as germanium or diamond. Alternatively, the substrate 202 may include a compound semiconductor such as silicon carbide (SiC), gallium arsenic, gallium phosphide, indium phosphide, indium arsenide, indium antimonide; an alloy semiconductor, such as SiGe, GaAsP, AlInAs, AlGaAs, GalnAs, GaInP, GaInAsP, and/or other suitable materials. Further, the substrate 202 may optionally include an epitaxial layer, may be strained for performance enhancement, may include a silicon-on-insulator structure, and/or may have other suitable enhancement features.

The stack 204 of alternating epitaxial semiconductor layers is blanketly deposited on the substrate 202. The stack 204 comprises alternating sacrificial semiconductor layers 206 and channel semiconductor layers 208 with the sacrificial semiconductor layer 206 being the topmost layer. In some embodiments, the sacrificial semiconductor layers 206 include a first semiconductor material, and the channel semiconductor layers 208 include a second semiconductor material that is different from the first semiconductor material. The materials of sacrificial semiconductor layers 206 and channel semiconductor layers 208 may be chosen based on providing different etching selectivities. For example, in some embodiments, the first semiconductor material may comprise germanium (Ge) or silicon germanium (SiGe), whereas the second semiconductor material may comprise silicon (Si). In some alternative embodiments, the first semiconductor material includes SiGe having a first Ge content, and the second semiconductor material includes SiGe having a second Ge content lower than the first Ge content. In some embodiments, the topmost sacrificial semiconductor layer, denoted as layer 206TL, is formed to have a higher etching rate than the underlying sacrificial semiconductor layers 206. For example, when the sacrificial semiconductor layers 206 are composed of SiGe, the topmost layer 206TL may include a higher Ge content than the underlying layers to increase its etching rate. In various embodiments, the sacrificial semiconductor layers 206 and the channel semiconductor layers 208 are substantially dopant-free (i.e., having an extrinsic dopant concentration less than about 1×10¹⁷ cm⁻).

The channel semiconductor layers 208 define channel nanostructures for a subsequently formed multi-gate device (e.g., GAA device 200), and their thicknesses are chosen based on the device performance considerations. In some embodiments, the channel semiconductor layers 208 have a thickness ranging from about 3 nm to about 10 nm. The channel semiconductor layers 208 may be substantially uniform in thickness.

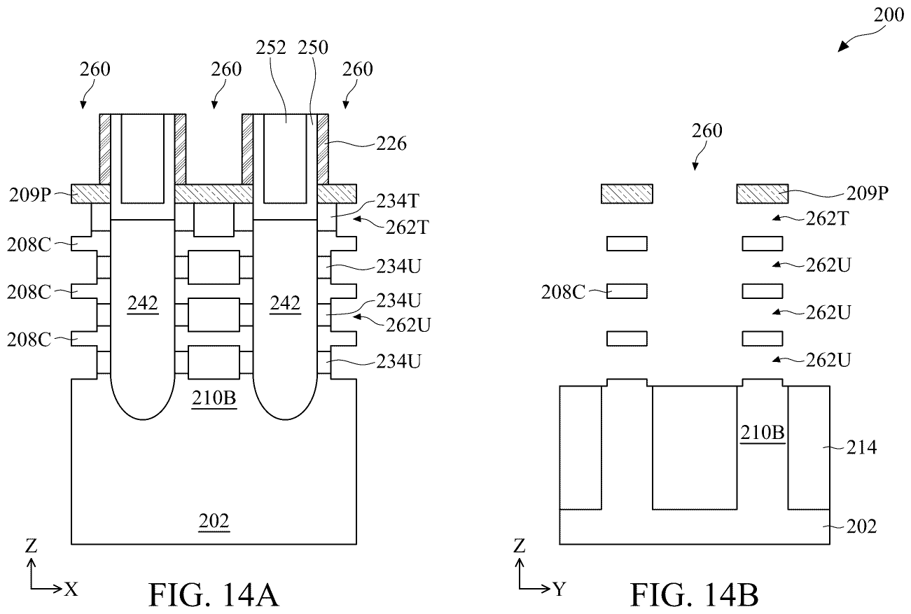

The sacrificial semiconductor layers 206 define gaps between adjacent channel nanostructures, within which a metal gate stack for the subsequently formed multi-gate is formed. Accordingly, the thickness of the sacrificial semiconductor layers 206 can be used to control the dimensions of the metal gate stack. In some embodiments, each sacrificial semiconductor layer 206 has the same thickness. In other embodiments, the topmost sacrificial semiconductor layer 206TL is formed with a thickness T1 greater than a thickness T2 of the underlying sacrificial semiconductor layers 206. The underlying sacrificial semiconductor layers 206 may be substantially uniform in thickness. In some embodiments, the thickness T1 of the topmost sacrificial semiconductor layer 206TL is about 0.5 nm to about 2 nm greater than the thickness T2 of the underlying sacrificial semiconductor layers 206. In some embodiments, the topmost sacrificial semiconductor layer 206TL may have a thickness ranging from about 6.5 nm to 17 nm, and the underlying sacrificial semiconductor layers 206 may have a thickness ranging from about 6 nm to 15 nm The number of sacrificial semiconductor layers 206 and channel semiconductor layers 208 depends on the desired number of channel nanostructures (e.g., 208C of FIGS. 14A and 14B) in the GAA device 200. In some embodiments, the number of channel semiconductor layers 208 is from, for example, 2 to 10, to form a stack of 2 to 10 vertically separated channel nanostructures. In some embodiments and as illustrated in FIG. 2, the stack 204 includes four (4) layers of sacrificial semiconductor layers 206 and three (3) layers of channel semiconductor layers 208.

The sacrificial semiconductor layers 206 and channel semiconductor layers 208 may be epitaxially grown layer-by-layer from the top surface of the substrate 202. In some embodiments, the sacrificial semiconductor layers 206 and channel semiconductor layers 208 may be grown by a molecular beam epitaxy (MBE) process, a chemical vapor deposition (CVD) process such as a metal organic CVD (MOCVD) process, or other suitable epitaxy growth processes. The epitaxy growth results in the sacrificial semiconductor layers 206 and the channel semiconductor layers 208 having the same crystal orientation as the substrate 202. In some embodiments, when the substrate 202 has a (100) surface crystal orientation, the sacrificial semiconductor layers 206 and the channel semiconductor layers 208 also exhibit a (100) surface crystal orientation.

The hard mask layer 209 is formed over the topmost sacrificial semiconductor layer 206TL. In some embodiments, the hard mask layer 209 may include silicon dioxide (SiO₂), silicon nitride (SiN), silicon oxynitride (SiON), silicon carbon nitride (SiCN), silicon oxycarbide (SiOC), silicon oxycarbon nitride (SiOCN), silicon carbide (SiC), aluminum oxide (Al₂O₃), hafnium oxide (HfO2), zirconium oxide (ZrO₂), or other suitable dielectric layer. In some embodiments, the hard mask layer 209 may be formed by CVD, plasma-enhanced CVD (PECVD), physical vapor deposition (PVD), atomic layer deposition (ALD), or other suitable deposition processes. In some embodiments, the hard mask layer 209 may have a double-layer structure including a pad oxide layer and a pad nitride layer formed over the pad oxide layer. In some embodiments, the pad oxide layer includes SiO₂, which may be formed by thermal oxidation, and the pad nitride layer includes SiN, which may be formed by CVD, PECVD, PVD, ALD, or other suitable deposition processes. The hard mask layer 209 serves as a gate protection layer configured to reduce damage to the underlying substrate 202 and the stack 204 during fabrication processes.

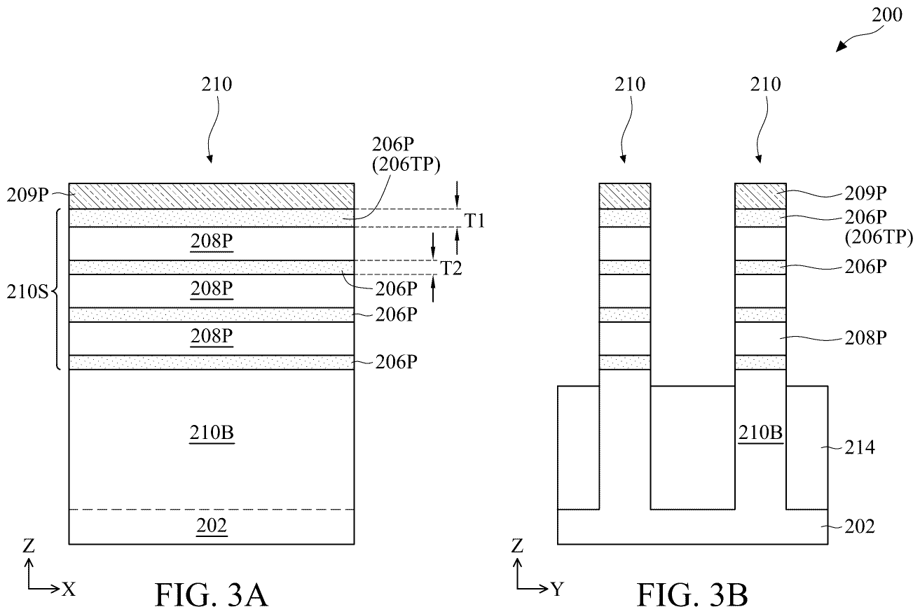

Referring to FIGS. 1 and 3A-3B, the method 100 proceeds to operation 104, where fin structures 210 are formed from the stack 204, in accordance with some embodiments. FIGS. 3A and 3B are cross-sectional views of the GAA device 200 after forming the fin structures 210. It should be noted that although two fin structures 210 are illustrated in FIG. 3B, any number of fin structures 210 may be formed.

In some embodiments, the hard mask layer 209, the stack 204, and a portion of the substrate 202 are patterned to form the fin structures 210. Each fin structure 210 extends vertically along the Z direction from the substrate 202 and has a length dimension along the X direction and a width dimension along the Y direction. The width of each fin structure 210 may range from about 10 nm to about 90 nm. Each fin structure 210 includes a base portion 210B, a stack portion 210S, and a hard mask portion 209P. The base portion 210B is formed from the substrate 202, the stack portion 210S is formed from the stack 204 and includes portions of the sacrificial semiconductor layers 206 (herein referred to as sacrificial semiconductor portions 206P with the topmost sacrificial semiconductor portion denoted as 206TP) and portions of the channel semiconductor layers 208 (herein referred to as channel semiconductor portions 208P), while the hard mask portion 209P is formed from the hard mask layer 209.

In some embodiments, the fin structures 210 may be formed using photolithography and etch processes. During a photolithography process, a photoresist layer is first applied to the hard mask layer 209 by, for example, spin coating. Then, the photoresist layer is exposed according to a mask of patterns, and is developed to form the patterns in the photoresist layer. The photoresist layer with the patterns can be used as an etch mask to pattern other layers. In some embodiments, patterning the photoresist layer is performed using an extreme ultraviolet (EUV) light lithography process. The patterned photoresist layer is then used to protect regions of the substrate 202 and the sacrificial semiconductor layers 206 and channel semiconductor layers 208 formed thereupon, while an etching process forms the fin structures 210. In some embodiments, the etching process may be a dry etching process such as plasma etching or reactive ion etching (RIE), a wet etching process, or a combination thereof.

In various other embodiments, the fin structures 210 may be formed using suitable processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process.

Mandrels are formed alongside the patterned sacrificial layer using a self-aligned process. The sacrificial layer is then removed, and the remaining mandrels are used as an etch mask to pattern the hard mask layer 209, the stack 204, and the substrate 202 to provide the fin structures 210.

Subsequently, an isolation feature 214 may be formed over the substrate 202 and on opposite sides of the fin structures 210. In some embodiments, the isolation feature 214 may include silicon dioxide, silicon nitride, silicon oxynitride, silicon carbonitride, silicon oxycarbonitride fluorine-doped silicate glass (FSG), a low-k dielectric, and/or other suitable dielectric materials. In an example process, the isolation feature 214 may be formed by first depositing a dielectric layer over the substrate 202, filling the trenches between the fin structures 210. In various examples, the dielectric layer may be deposited by a CVD process, a subatmospheric CVD (SACVD) process, a flowable CVD process, an atomic layer deposition (ALD) process, a physical vapor deposition (PVD) process, spin-on coating, and/or other suitable process. The deposited dielectric material is then planarized, for example, by a chemical mechanical polishing (CMP) process. The planarized dielectric layer is further recessed using a suitable anisotropic etching process to expose the stack portions 210S of the fin structures 210.

In some embodiments, the anisotropic etching process is a dry etching process, a wet etching process, and/or a combination thereof. In some embodiments and as shown in FIG. 3B, a top surface of the isolation feature 214 is lower than a bottom surface of the bottommost sacrificial semiconductor portions 206P, so that the stack portion 210S rises above the isolation feature 214.

Because the hard mask portions 209P are formed from a dielectric material having high etching selectivity relative to the isolation feature 214, the hard mask portions 209P remain in the structure after the isolation feature 214 is formed.

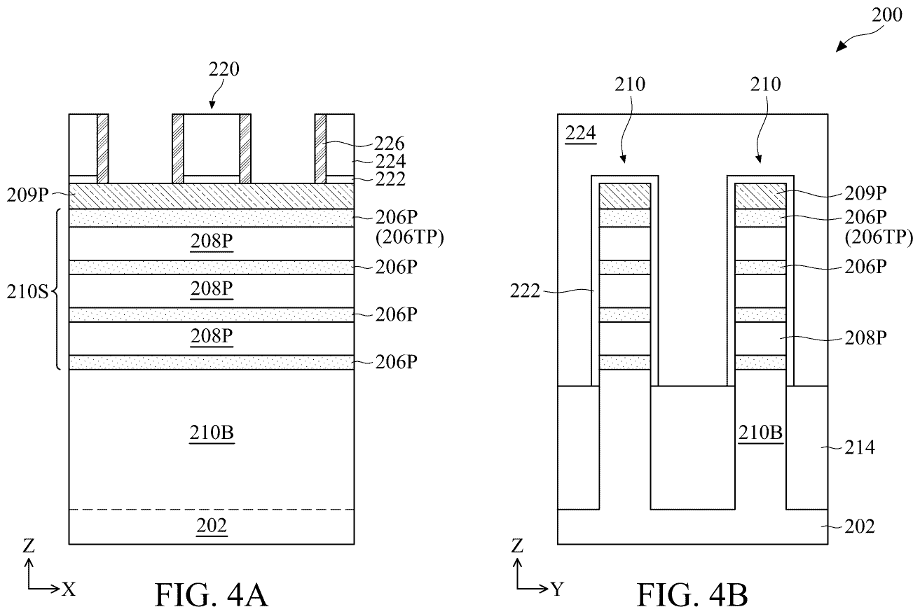

Referring to FIGS. 1 and 4A-4B, the method 100 proceeds to operation 106, where sacrificial gate structures 220 are formed over the fin structures 210 and the isolation feature 214, in accordance with some embodiments. FIGS. 4A and 4B are cross-sectional views of the GAA device 200 after forming the sacrificial gate structures 220.

The sacrificial gate structures 220 extend longitudinally in parallel and are spaced apart by a distance ranging from, for example, about 10 nm to 25 nm. In some embodiments and as shown in FIG. 4A, each of the sacrificial gate structures 220 wraps around the fin structures 210, covering the top and sidewall surfaces of the hard mask portions 209P as well as the sidewall surfaces of the sacrificial and channel semiconductor portions 206P and 208P. The sacrificial gate structure 220 serves as a placeholder and will later be replaced with a metal gate structure.

In some embodiments, each of the sacrificial gate structures 220 may include a sacrificial gate stack (222, 224) and gate spacers 226 on sidewalls of the sacrificial gate stack (222, 224). In some embodiments, the sacrificial gate stack (222, 224) includes, from bottom to top, a sacrificial gate dielectric 222 and a sacrificial gate electrode 224. In some embodiments, the sacrificial gate dielectric 222 may include silicon oxide, silicon nitride, or silicon oxynitride. The sacrificial gate electrode 224 may include silicon such as polycrystalline silicon or amorphous silicon.

In some embodiments, the sacrificial gate stacks (222, 224) may be formed by first conformally depositing a sacrificial gate dielectric layer over the fin structures 210 and the isolation feature 214. The sacrificial gate dielectric layer may be deposited by CVD, PECVD, ALD, or other suitable conformal deposition processes. The thickness of the sacrificial gate dielectric layer may range from about 1 nm to about 5 nm in some embodiments. A sacrificial gate electrode layer is then blanketly deposited on the sacrificial gate dielectric layer such that the fin structures 210 are fully embedded in the sacrificial gate electrode layer. The sacrificial gate electrode layer may be deposited using CVD, PECVD, PVD, ALD, or other suitable deposition processes. The thickness of the sacrificial gate electrode layer may range from about 100 nm to about 200 nm in some embodiments. In some embodiments, the sacrificial gate electrode layer is subjected to a planarization operation after deposition. Subsequently, the sacrificial gate electrode layer and the sacrificial gate dielectric layer are patterned using photolithography and etching processes. For example, a photoresist layer (not shown) is applied over the sacrificial gate electrode layer and lithographically patterned by lithographic exposure and development. The pattern in the photoresist layer is sequentially transferred into the sacrificial gate electrode layer and the sacrificial gate dielectric layer by at least one anisotropic etching process, thereby forming the sacrificial gate stacks (222, 224) comprising the remaining portions of the sacrificial gate electrode layer and the sacrificial gate dielectric layer. The anisotropic etching process may be a dry etching process, for example, RIE, a wet etching process, or a combination thereof. If not completely consumed, the remaining photoresist layer after formation of the sacrificial gate stacks (222, 224) is removed by, for example, ashing.

Next, a gate spacer layer is deposited on exposed surfaces of the GAA device 200 by a conformal deposition process, such as, for example, ALD or CVD. The gate spacer layer may include a dielectric material such as, for example, an oxide, a nitride, an oxynitride, or combinations thereof. In some embodiments, the gate spacer layer is made of silicon nitride. In some embodiments, after deposition, an anisotropic etching process may be performed to remove horizontal portions of the gate spacer layer. Remaining portions of the gate spacer layer on the sidewalls of the sacrificial gate stacks (222, 224) constitute the gate spacers 226.

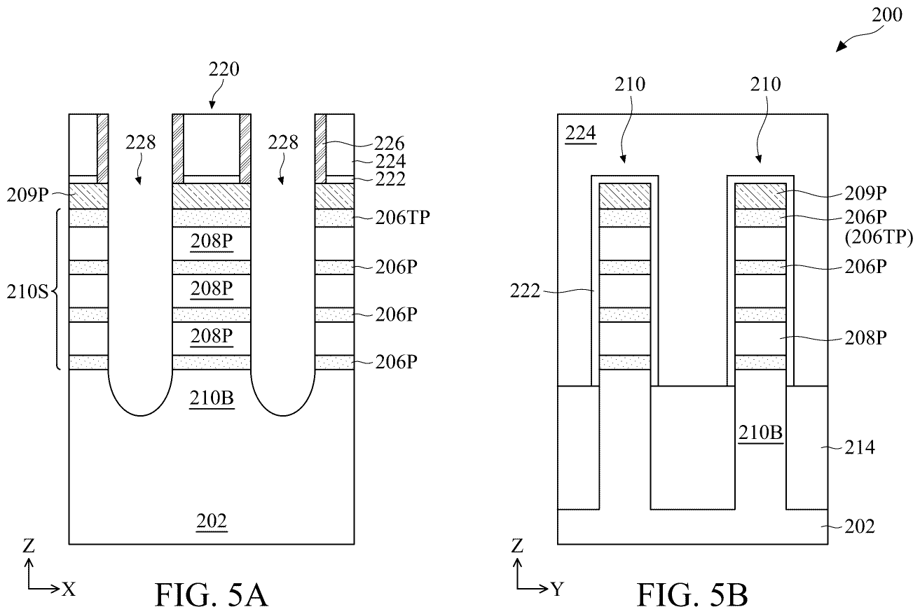

Referring to FIGS. 1 and 5A-5B, the method 100 proceeds to operation 108, where source/drain trenches 228 are formed in the fin structures 210, in accordance with some embodiments. FIGS. 5A and 5B are cross-sectional views of the GAA device 200 after forming the source/drain trenches 228.

The source/drain trenches 228 may extend through the hard mask portion 209P and the underlying stack portion 210S. In some embodiments, the hard mask portion 209P, the sacrificial semiconductor portions 206P, and the channel semiconductor portions 208P in the source/drain regions, or regions not covered by the sacrificial gate structures 220, are etched using the sacrificial gate structures 220 as an etch mask to form the source/drain trenches 228.

The etching may be performed by an anisotropic dry etching process, such as plasma etching or RIE. An example dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof.

Alternatively, the etching may be performed by an anisotropic wet etching process that uses an etchant such as a mixture of ammonium hydroxide, hydrogen peroxide, and water (APM), tetramethylammonium hydroxide (TMAH), or ammonium hydroxide (NH₄OH). As shown in FIG. 5A, sidewalls of the hard mask portions 209P, the sacrificial semiconductor portions 206P, and the channel semiconductor portions 208P are exposed in the source/drain trenches 228. In some embodiments, the base portions 210B may also be partially etched, so that the source/drain trenches 228 extend into the base portion 210B. Accordingly, the bottom surfaces of the source/drain trenches 228 may be leveled with the top surface of the base portion 210B or lower than the top surface of the base portion 210B. In some embodiments, the portion of the hard mask portion 209P and the stack portion 210S of each fin structure 210 between the sacrificial gate structure 220 is completely removed, exposing the base portion 210B of each fin structure 210.

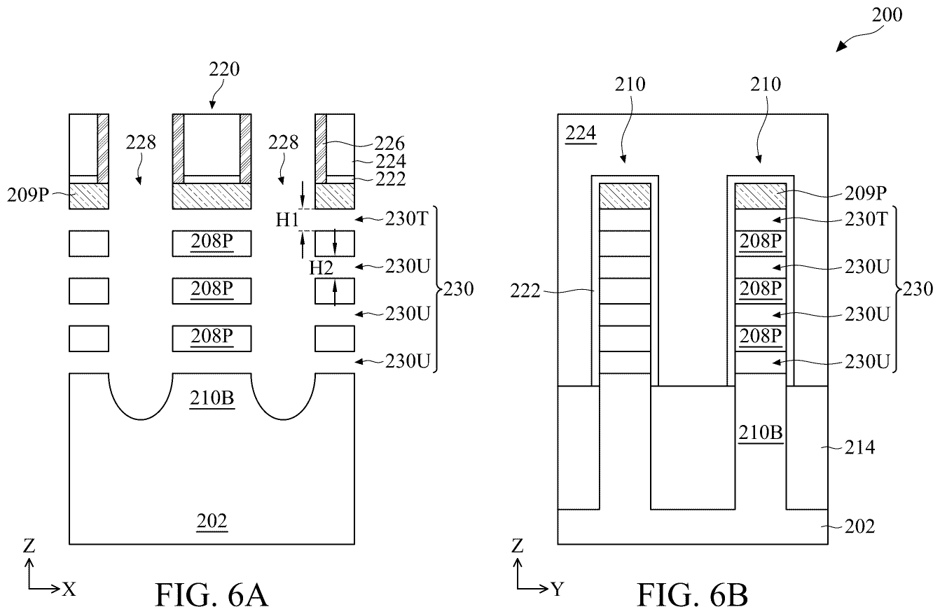

Referring to FIGS. 1 and 6A-6B, the method 100 proceeds to operation 110, where the sacrificial semiconductor portions 206P are removed, in accordance with some embodiments. FIGS. 6A and 6B are cross-sectional views of the GAA device 200 after removing the sacrificial semiconductor portions 206P.

The selective removal of the sacrificial semiconductor portions 206P releases the channel semiconductor portions 208P, thereby forming gaps 230 within the structure. In each fin structure 210, the gaps 230 include a first gap 230T, which is the topmost gap located between the hard mask portion 209P and the topmost channel semiconductor portion 208P. The gaps 230 further include a plurality of second gaps 230U, which are positioned below the first gap 230T and are located between adjacent channel semiconductor portions 208P, as well as between the bottommost channel semiconductor portions 208P and the base portion 210B of the fin structure 210. The first gap 230T results from the removal of the topmost sacrificial semiconductor layer 206TL, while the second gaps 230U result from the removal of the underlying sacrificial semiconductor layers 206. As a result, the height H1 of the first gap 230T is greater than the height H2 of the second gaps 230U.

In some embodiments, the sacrificial semiconductor portions 206P may be removed by a selective etching process using an etchant that is selective to the material of sacrificial semiconductor portions 206P, such that the sacrificial semiconductor portions 206P are removed without substantially attacking the channel semiconductor portions 208P. In some embodiments, the etching process is an isotropic etching process which can be a dry etching process or a wet etching process. In some embodiments, the selective etching process may include oxidizing the sacrificial semiconductor portions 206P using a suitable oxidizer, such as ozone. Thereafter, the oxidized sacrificial semiconductor portions 206P may be selectively removed. In some embodiments, when the channel semiconductor portions 208P include Si and the sacrificial semiconductor portions 206P include SiGe, the sacrificial semiconductor portions 206P may be selectively removed by applying an HCl gas at a temperature of about 500° C. to about 700° C., or applying a gas mixture of CF₄, SF₆, and CHF₃.

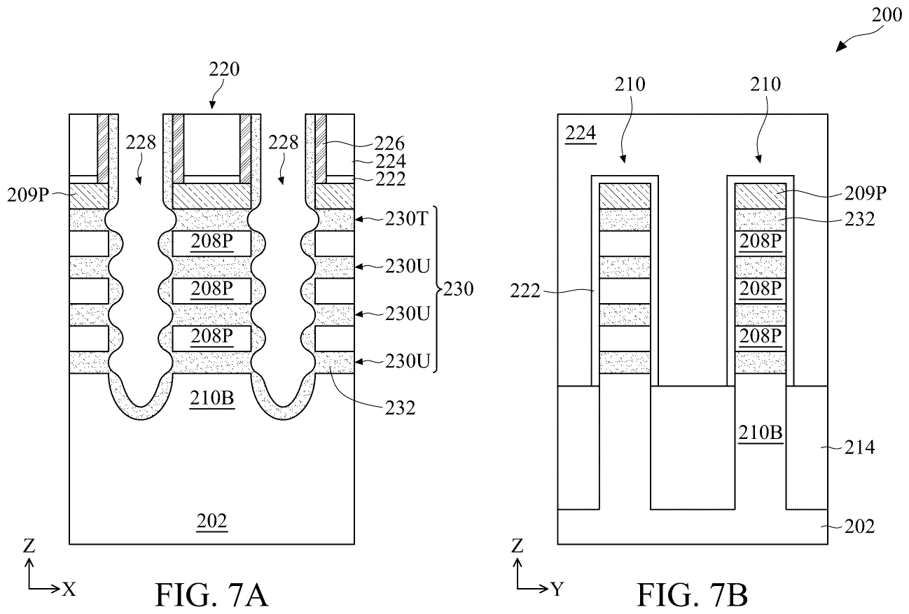

Referring to FIGS. 1 and 7A-7B, the method 100 proceeds to operation 112, where a sacrificial dielectric layer 232 is formed over exposed surfaces of the source/drain trenches 228 and the sacrificial gate structures 220, as well as within the gaps 230, in accordance with some embodiments. FIGS. 7A and 7B are cross-sectional views of the GAA device 200 after forming the sacrificial dielectric layer 232.

The sacrificial dielectric layer 232 is conformally deposited on the channel semiconductor portions 208P, the base portion 210B, and the hard mask portions 209P to fill the gaps 230. In some embodiments, the sacrificial dielectric layer 232 may include a dielectric oxide, such as, for example, silicon dioxide or a silicon-rich oxynitride. The sacrificial dielectric layer 232 may be formed by a conformal deposition process such as CVD or ALD. In some embodiments, the thickness of the sacrificial dielectric layer 232 is controlled such that the sacrificial dielectric layer pitches off the first and second gaps 230T, 230U. In some embodiments, the sacrificial dielectric layer fully fills both the first gap 230T and the second gaps 230U. In other embodiments and as shown in FIG. 7A, the sacrificial dielectric layer 232 fully fills the second gaps 230U such that sidewall surfaces of portions of the sacrificial dielectric layer 232 within the second gaps 230U extend laterally beyond sidewall surfaces of the channel semiconductor portions 208P. However, due to the greater height H1 of the first gaps 230T compared to the height H2 of the second gaps 230U, the sacrificial dielectric layer 232 only partially fills the first gaps 230T. As a result, sidewall surfaces of a portion of the sacrificial dielectric layer 232 within the first gaps 230T are recessed relative to, and do not extend laterally beyond, the sidewall surfaces of the channel semiconductor portions 208P.

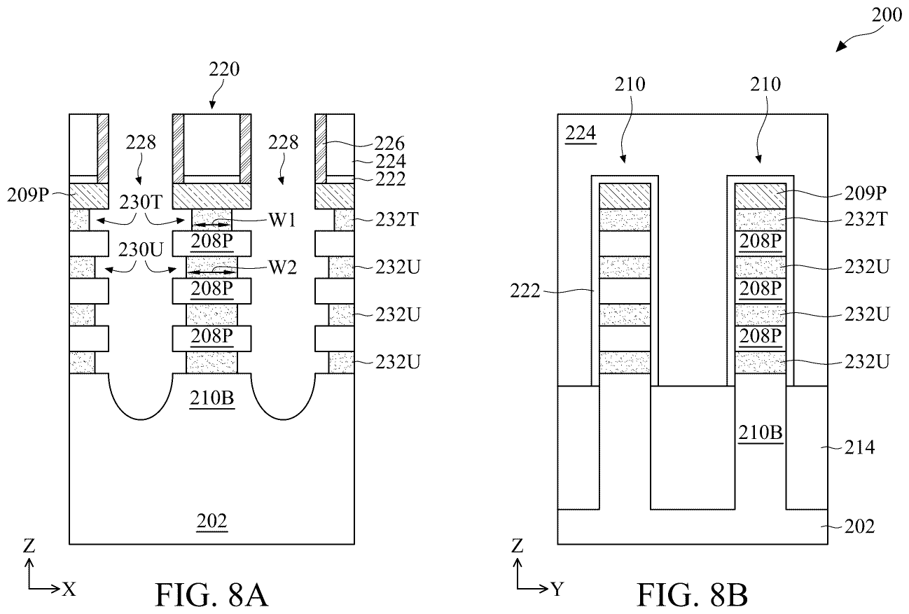

Referring to FIGS. 1 and 8A-8B, the method 100 proceeds to operation 114, where the sacrificial dielectric layer 232 is recessed to form first sacrificial dielectric portions 232T within the first gaps 230T and second sacrificial dielectric portions 232U within the second gaps 230U, in accordance with some embodiments. FIGS. 8A and 8B are cross-sectional views of the GAA device 200 after recessing the sacrificial dielectric layer 232 to the first sacrificial dielectric portions 232T and the second sacrificial dielectric portions 232U.

An etching process, for example, an isotropic etching process, may be performed to recess portions of the sacrificial dielectric layer 232 exposed by the source/drain trenches 228, thereby forming the first sacrificial dielectric portions 232T within the first gaps 230T and the second sacrificial dielectric portions 232U within the second gaps 230U. Within each fin structure 210, the first sacrificial dielectric portion 232T is the topmost portion, positioned above the second sacrificial dielectric portions 232U.

In embodiments of the present disclosure, the first gap 230T has a greater height H1 than the height H2 of the second gaps 230U, resulting in a thicker portion of the sacrificial dielectric layer 232 within the first gap 230T relative to the portions of the sacrificial dielectric layer 232 within the second gaps 230U. Accordingly, the portion of the sacrificial dielectric layer 232 in the first gap 230T is recessed to a greater extent than the portions of the sacrificial dielectric layer 232 in the respective second gaps 230U. As a result, the width W1 of the first sacrificial dielectric portion 232T is less than the width W2 of the second sacrificial dielectric portions 232U. In some embodiments, the etching process is controlled such that the sidewalls of the second sacrificial dielectric portions 232U are aligned with the inner sidewall of the gate spacers 226, while the sidewalls of the first sacrificial dielectric portion 232T are recessed inward from the inner sidewalls of the gate spacers 226. In some embodiments, the second sacrificial dielectric portions 232U have substantially the same width.

The etching process selectively removes the material of the sacrificial dielectric layer 232 without substantially etching the semiconductor material forming the channel semiconductor portions 208P and the substrate 202, or the dielectric material forming the gate spacers 226. In some embodiments, the isotropic etching may be an isotropic dry etching process using an etching gas composition including a halogen-containing compound, ammonia (NH₃), and an amine. In some embodiments, the halogen-containing compound is a fluorine-containing compound. In some embodiments, the fluorine-containing compound may include, but not limited to, hydrogen fluoride (HF), carbon tetrafluoride (CF₄), trifluoromethane (CHF₃), sulfur hexafluoride difluoromethane (CH₂F₂) and hexafluoroethane (C2F₆). In some embodiments, the amine may include, but not limited to, methylamine, dimethylamine, trimethylamine, ethylamine, diethylamine, triethylamine, methylethylamine, N,N-diethylmethylamine, N,N-dimethylethylamine, isopropylamine, N-ethyldiisopropylamine, and tert-butylamine. In some embodiments, the etching gas composition comprises hydrogen fluoride, ammonia, and trimethyl amine.

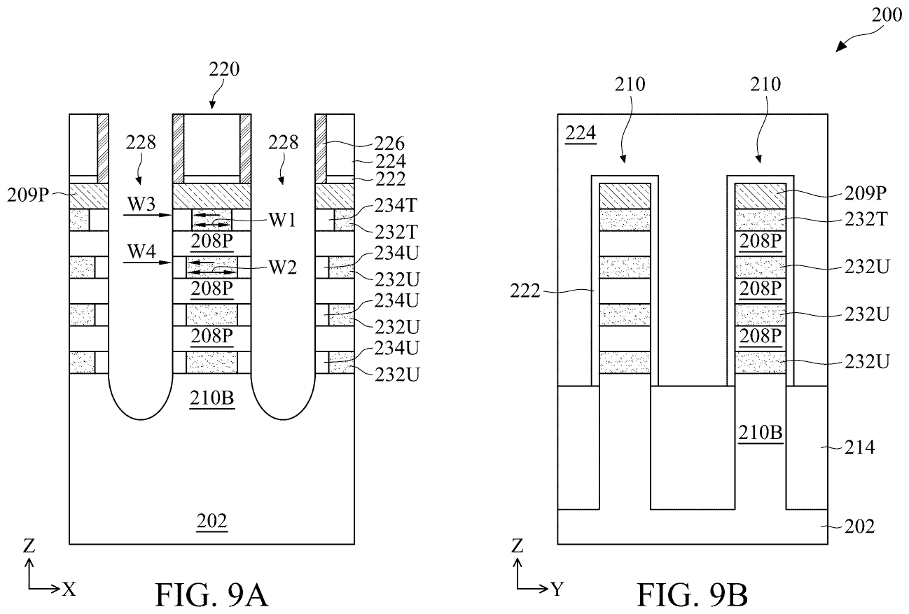

Referring to FIGS. 1 and 9A-9B, the method 100 proceeds to operation 116, wherein first inner spacers 234T are formed in the first gaps 230T and second inner spacers 234U are formed in the second gaps 230U, in accordance with some embodiments. FIGS. 9A and 9B are cross-sectional views of the GAA device 200 after forming the first inner spacers 234T and the second inner spacers 234U.

In each fin structure 210, the first inner spacer 234T is the topmost inner spacer, located above the second inner spacers 234U. The first inner spacer 234T laterally surrounds the first sacrificial dielectric portion 232T, while each second inner spacer 234U laterally surrounds a corresponding second sacrificial dielectric portion 232U. Sidewalls of the first and second inner spacers 234T, 234U are aligned with outer sidewalls of the gate spacers 226.

In some embodiments and as shown in FIG. 9A, the first inner spacers 234T, which are formed in the first gaps 230T and contact the sidewalls of the first sacrificial dielectric portions 232T, have a width W3 that may be greater than the width of the gate spacers 226. In contrast, the second inner spacers 234U, formed in the second gaps 230U and contacting the sidewalls of the second sacrificial dielectric portions 232U, have a width W4 that may be the same as the width of the gate spacers 226. Accordingly, the width W3 is greater than the width W4. In some embodiments, the width W3 is about 0.25 to about 2.5 nm greater than the width W4.

To form the inner spacers 234T, 234U, an inner spacer material layer is deposited over the structure, including in the first and second gaps 230T, 230U. The inner spacer material layer may include a dielectric nitride, for example, silicon nitride, silicon oxycarbonitride, silicon carbonitride, or any suitable dielectric material having a different etching selectivity from the dielectric oxide forming the first and second sacrificial dielectric portions 232T, 232U. The inner spacer material layer may be formed by CVD, ALD or any other suitable conformal deposition processes. In some embodiments, the inner spacer material layer may be formed to have a thickness such that the remaining volumes of the first and second gaps 230T, 230U not occupied by the first and second sacrificial dielectric portions 232T, 232U are filled by the inner spacer material layer.

An etching process, such as an anisotropic etching process, is then performed to remove portions of the inner spacer material layer disposed outside the first and second gaps 230T, 230U. The remaining portions of the inner spacer material layer (i.e., portions disposed inside the first and second gaps 230T, 230U) form the inner spacers 234T and 234U. In some embodiments, the anisotropic etching process may be a wet etching process that includes use of an etchant such as, for example, buffered hydrofluoric acid (BHF), hydrofluoric acid (HF), hydrofluoric nitric acid (HNA), phosphoric acid, HF diluted by ethylene glycol (HFEG), hydrochloric acid (HCl), or any combination thereof. In some embodiments, the anisotropic etching process may be a dry etching process that includes use of an oxygen-containing gas, hydrogen, nitrogen, a fluorine-containing gas (e.g., CF₄, SF₆, CH₂F₂, CHF₃, and/or C₂F₆), a chlorine-containing gas (e.g., Cl₂, CHCl₃, CCl, and/or BCl₃), a bromine-containing gas (e.g., HBr and/or CHBr₃), an iodine-containing gas (e.g., CF₃I), other suitable gases and/or plasmas, and/or combinations thereof.

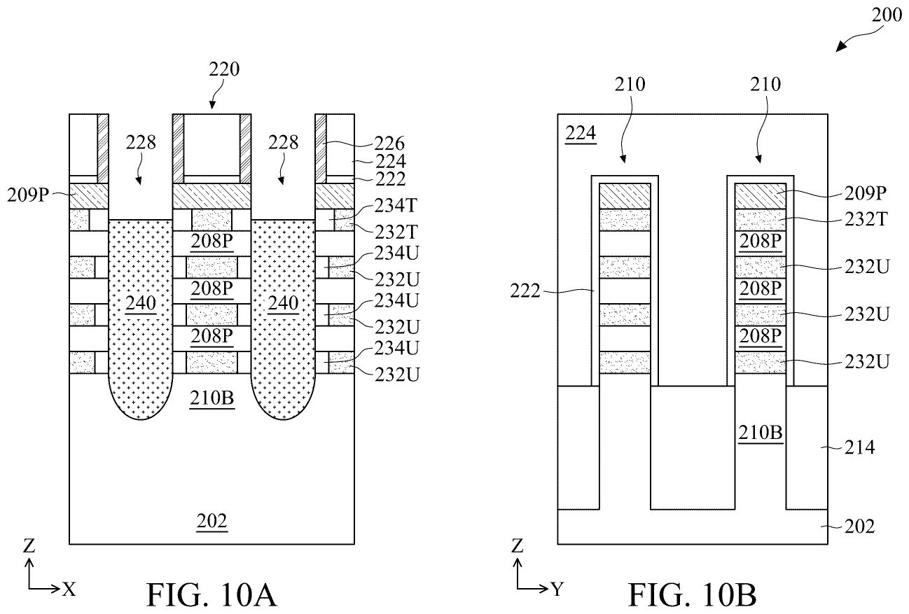

Referring to FIGS. 1 and 10A-10B, the method 100 proceeds to operation 118, where epitaxial semiconductor features 240 are formed in the source/drain trenches 228, in accordance with some embodiments. FIGS. 10A and 10B are cross-sectional views of the GAA device 200 after forming the epitaxial semiconductor features 240 in the source/drain trenches 228.

The epitaxial semiconductor features 240 are disposed on opposite sides of the sacrificial gate structure 220 and are in contact with the channel semiconductor portions 208P and the first and second inner spacers 234T, 234U.

The epitaxial semiconductor features 240 are epitaxially grown from semiconductor surfaces exposed by the source/drain trenches 228, including the sidewall surfaces of the channel semiconductor portions 208P, the sidewall and bottom surfaces of the substrate 202, but not from the dielectric surfaces such as surfaces of the first and second inner spacers 234T, 234U and the gate spacers 226. The epitaxial semiconductor features 240 thus can grow both vertically and horizontally to form facets, which may correspond to crystalline planes of the substrate 202. The epitaxial semiconductor features 240 may be formed by, for example, vapor-phase epitaxy (VPE), ultra-high vacuum CVD (UHV-CVD), low pressure CVD (LPCVD, plasma-enhanced CVD (PECVD), molecular beam epitaxy (MBE), or other suitable selective epitaxy growth processes. The epitaxial semiconductor features 240 formed may have top surfaces above a top surface of the topmost channel semiconductor portion 208P. In some embodiments, the top surface of the epitaxial semiconductor features 240 may be coplanar with or below the bottom surface of the hard mask portion 209P.

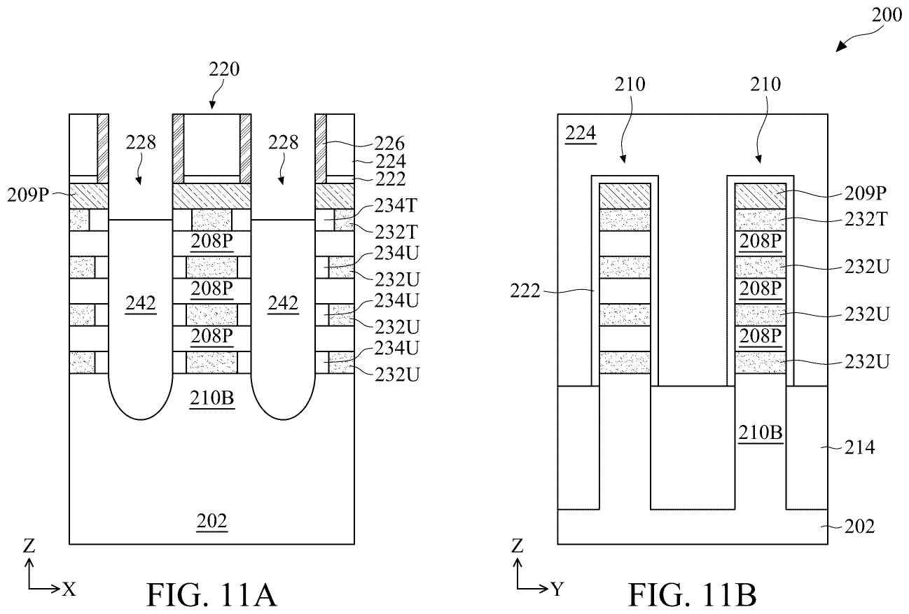

The epitaxial semiconductor features 240 may include any suitable material for n-type or p-type FET devices. For example, when n-type FET devices are formed, the epitaxial semiconductor features 240 may include materials exerting a tensile strain in the channel regions, such as Si, SiC, SiCP, SiP, or the like. Likewise, when p-type FET devices are formed, the epitaxial semiconductor features 240 may include materials exerting a compressive strain in the channel regions, such as Si, SiGe, SiGeB, Ge, GeSn, Referring to FIGS. 1 and 11A-11B, the method 100 proceeds to operation 120, where dopants are implanted into epitaxial semiconductor features 240 to form source/drain features 242, in accordance with some embodiments. FIGS. 10A and 10B are cross-sectional views of the GAA device 200 after forming the source/drain features 242.

An implantation process may be performed to introduce the dopants into the epitaxial semiconductor features 240, thereby forming source/drain features 242 which are doped epitaxial semiconductor regions. In some embodiments, the dopant may be a p-type dopant, such as boron (B), aluminum (Al), gallium (Ga), or indium (In). For example, the source/drain features 242 of a p-type FET device may comprise boron-doped SiGe. In some embodiments, the dopant may be an n-type dopant, such as phosphorus (P) or arsenic (As). For example, the source/drain features 242 of an n-type FET device may comprise phosphorus-doped Si. The concentration of the p-type or n-type dopant may range from about 1×10¹⁹ atoms/cm³ to about 1×10²¹ atoms/cm³, such as about 5×10²⁰ atoms/cm³. In some embodiments, the implantation is performed vertically. In some embodiments, the source/drain feature 242 has a gradient doping profile, with the dopant concentration gradually decreasing from the top toward the bottom of the source/drain feature 242. After implantation, an anneal may be performed to repair implant damage and to activate the dopants.

In some embodiments, the epitaxial semiconductor features 240 may be in situ doped during growth, in which case operation 120 may be omitted.

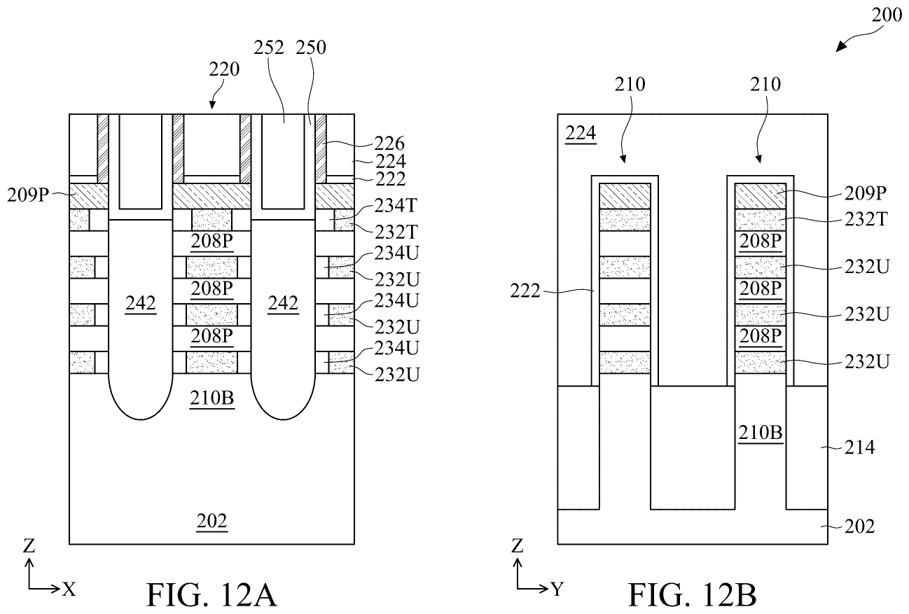

Referring to FIGS. 1 and 12A-12B, the method 100 proceeds to operation 122, where a contact etch stop layer (CESL) 250 is formed over the source/drain features 242, followed by forming an interlayer dielectric (ILD) layer 252 over the contact etch stop layer 250, in accordance with some embodiments. FIGS. 12A and 12B are cross-sectional views of the GAA device 200 after forming the contact etch stop layer 250 and the ILD layer 252.

In some embodiments, the contact etch stop layer 250 is conformally deposited on the source/drain features 242, the first inner spacers 234T, the hard mask portions 209P, the gate spacers 226, and the sacrificial gate electrode 224. The contact etch stop layer 250 may include a dielectric material such as silicon nitride, silicon carbon, silicon oxynitride, silicon oxycarbide, or combinations thereof. The contact etch stop layer 250 may be formed using a conformal deposition process such as ALD, or CVD, for example.

The ILD layer 252 is disposed over the contact etch stop layer 250, having a different etching rate than the contact etch stop layer 250. In some embodiments, the ILD layer 252 may include a low-k dielectric material having a dielectric constant lower than the dielectric constant (about 3.9) of silicon dioxide. The low-k dielectric material may include phosphosilicate glass (PSG), borosilicate glass (BSG), borophosphosilicate glass (BPSG), undoped silicate glass (USG), fluorinated silicate glass (FSG), spin-on-glass (SOG), or combinations thereof. The ILD layer 252 may be deposited by CVD, flowable CVD (FCVD), PECVD, spin coating, or other suitable deposition processes.

After deposition of the ILD layer 252, a planarization process, such as a CMP process, may be performed to remove portions of the ILD layer 252 and the contact etch stop layer 250 from the topmost surfaces of the sacrificial gate structures 220. Accordingly, the topmost surfaces of the sacrificial gate structure 220 are exposed. In some embodiments, the top surfaces of the ILD layer 252 and the contact etch stop layer 250 are coplanar with the topmost surfaces of the sacrificial gate structures 220 (i.e., the top surfaces of the gate spacers 226 and sacrificial gate electrodes 224).

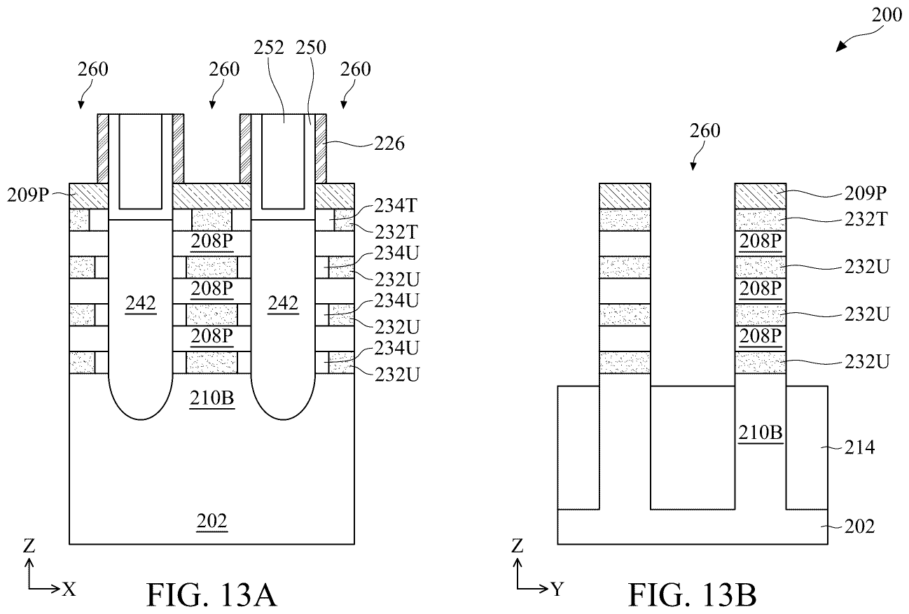

Referring to FIGS. 1 and 13A-13B, the method 100 proceeds to operation 124, where the sacrificial gate stacks (222, 224) are removed, in accordance with some embodiments. FIGS. 13A and 13B are cross-sectional views of the GAA device 200 after removing the sacrificial gate stacks (222, 224).

One or more etching processes may be performed to selectively remove various components of each sacrificial gate stack (222, 224), including the sacrificial gate dielectric 222 and the sacrificial gate electrode 224. The removal of each sacrificial gate stack (222, 224) forms a gate trench 260 that exposes the hard mask portion 209P, the channel semiconductor portions 208P, and the sacrificial dielectric portions 232T, 232U in the channel region of each fin structure 210. The ILD layer 252 and contact etch stop layer 250 protect the source/drain features 242 during the etching process. The etching process may be a dry etching process, a wet etching process, or a combination thereof. The etching process can be tuned such that the sacrificial gate dielectric 222 and the sacrificial gate electrode 224 are removed without (or minimally) etching other elements in the GAA device 200, including the ILD layer 252, the contact etch stop layer 250, the source/drain features 242, the gate spacers 226, and the hard mask portion 209P. For example, in instances where the sacrificial gate electrode 224 is composed of polysilicon and the ILD layer 252 is composed of silicon oxide, a wet etchant such as a TMAH solution may be used to selectively remove the sacrificial gate electrode 224. The sacrificial gate dielectric 222 is thereafter removed using plasma dry etching and/or wet etching.

Referring to FIGS. 1 and 14A-14B, the method 100 proceeds to operation 126, where the sacrificial dielectric portions 232T, 232U are removed, in accordance with some embodiments. FIGS. 14A and 14B are cross-sectional views of the GAA device 200 after removing the sacrificial dielectric portions 232T, 232U.

The selective removal of the sacrificial dielectric portions 232T, 232U releases the channel semiconductor portions 208P to form channel nanostructures 208C. In some embodiments, the channel nanostructures 208C are nanosheets. In some embodiments, the sacrificial dielectric portions 232T, 232U may be removed by a selective etching process using an etchant that is selective to the material of sacrificial dielectric portions 232T, 232U, such that the sacrificial dielectric portions 232T, 232U are removed without substantially attacking the channel semiconductor portions 208P, the gate spacers 226, the inner spacers 234T, 234U, the ILD layer 252, and the contact etch stop layer 250. In some embodiments, the etching process is an isotropic etching process which can be a dry etching process or a wet etching process. The inner spacers 234T, 234U serve as etch stop layers to protect the source/drain features 242 during removal of the sacrificial dielectric portions 232T, 232U.

In some embodiments, after exposing the channel nanostructures 208C by removing the sacrificial dielectric portions 232T, 232U, a trimming operation may be performed to reduce the thickness of the channel nanostructures 208C, thereby improving the gate fill window. The trimming operation can utilize any suitable etching process, such as dry etching, wet etching, or a combination of both. The resulting channel nanostructures 208C may have a thickness ranging from 3 nm to 8 nm.

As shown in FIG. 14A, within each fin structure 210, a first gate gap 262T is formed between the topmost channel nanostructure 208C and the hard mask portion 209P, while second gate gaps 262U are formed between adjacent channel nanostructures 208C as well as between the bottommost channel nanostructure 208C and the base portion 210B, as a result of the removal of the sacrificial dielectric portions 232T, 232U and nanosheet trimming. The second gate gaps 262U define the spacing between adjacent channel nanostructures 208C. In some embodiments, the spacing between the adjacent channel nanostructures 208C (also referred to as sheet-to-sheet spacing) may range from about 8 nm to about 15 nm. The first gate gap 262T, located above the second gate gaps 262U, defines the spacing between the hard mask portion 209P and the topmost channel nanostructure 208C. The first gate gap 262T has a greater height but a smaller width compared to the second gate gaps 262U. In some embodiments, the height of the first gate gap 262T is about 0.5 nm to about 2 nm greater than that of the second gate gaps 262U, and the width of the first gate gap 262T is about 0.5 nm to about 5 nm smaller than that of the second gate gaps 262U.

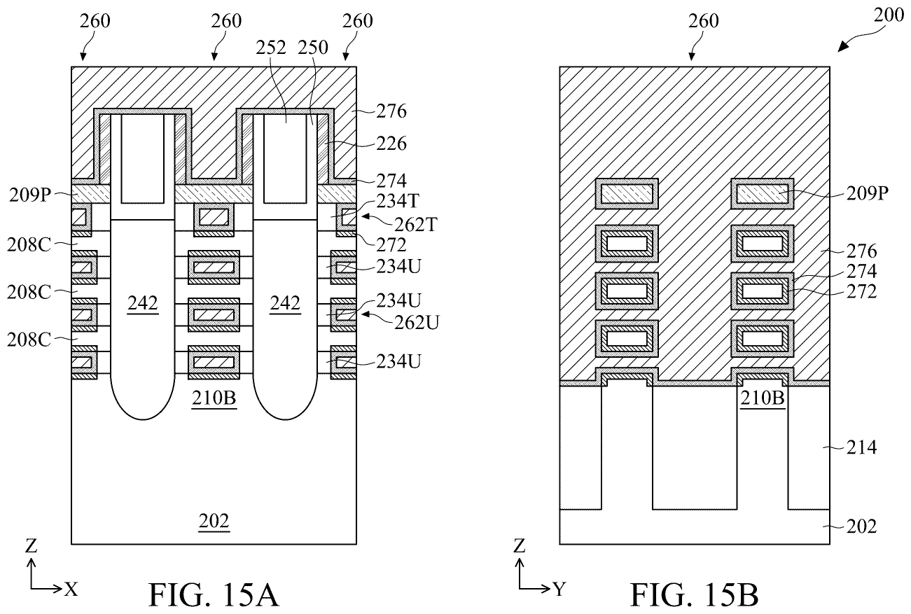

Referring to FIGS. 1 and 15A-15B, the method 100 proceeds to operation 128, where interfacial layers 272, gate dielectric layers 274, and gate electrode layers 276 are formed for replacement gates, in accordance with some embodiments. FIGS. 15A and 15B are cross-sectional views of the GAA device 200 after forming the interfacial layers 272, gate dielectric layers 274, and gate electrode layers 276.

The interfacial layers 272 are formed on the exposed surfaces of the channel nanostructures 208C and the base portions 210B, such as on top surface, sidewalls, and bottom surface of the channel nanostructures 208C, and on top surfaces and sidewalls of the base portions 210B. The interfacial layers 272 can promote adhesion of the gate dielectric layers 274 to the channel nanostructures 208C. In some embodiments, the interfacial layers 272 may include a dielectric material such as silicon oxide. In some embodiments, the interfacial layers 272 may be formed by chemical oxidation or thermal oxidation of surface portions of the channel nanostructures 208C and the base portions 210B. For example, in some embodiments, the interfacial layers 272 are formed using an ozonated deionized water comprising ozone. The thickness of the interfacial layers 272 ranges from about 0.5 nm to about 1.5 nm. In some embodiments, the interfacial layers 272 are about 1 nm thick, achieved by oxidizing around 1 nm of the channel nanostructures 208C.

Afterwards, the gate dielectric layers 274 are conformally deposited in the gate trenches 260 and the gate gaps 262T, 262U. The gate dielectric layers 274 wrap around the channel nanostructures 208C and the hard mask portion 209P, such that the gate dielectric layers 274 are disposed on top surfaces, sidewalls, and bottom surfaces of the interfacial layers 272, on sidewalls and bottom surfaces of the gate trenches 260, and on top surfaces of the gate spacers 226, contact etch stop layer 250, and ILD layer 252. In some embodiments, the gate dielectric layers 274 may include a high-k dielectric material having a dielectric constant greater than silicon dioxide. Examples of high-k dielectric materials include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), titanium oxide (TiO₂), and hafnium oxide-alumina (HfO₂-Al₂O₃) alloy. The gate dielectric layers 274 may be formed by CVD, ALD or other suitable conformal deposition methods. In some embodiments, the gate dielectric layers 274 may be formed using a conformal deposition process such as ALD in order to ensure that the high-k gate dielectric layers 274 has a uniform thickness around each of channel nanostructures 208C. The gate dielectric layers 274 may be formed to have a thickness ranging from about 1 nm to about 2.5 nm. In some embodiments, the gate dielectric layers 274 may be formed to have a thickness of about 1.5 nm.

The gate electrode layers 276 are deposited over the gate dielectric layers 274, respectively, and fill the remaining volumes of the gate trenches 260 and gate gaps 262T, 262U. The gate electrode layers 276 may include a metal-containing material such as titanium aluminum (TiAl), titanium aluminum carbide (TiAlC), tantalum aluminum carbide (TaAlC), tantalum aluminum silicide (TaSiAl), tantalum silicon carbide (TaSiC), tantalum silicide (TaSi), hafnium carbide (HfC), tungsten nitride (WN), tungsten carbon nitride (WCN), tantalum silicon nitride (TaSiN), tantalum nitride (TaN). cobalt, ruthenium, aluminum, tungsten, combinations thereof, or multi-layers thereof. For example, although single-layer gate electrode layers 276 are illustrated in FIGS. 15A, 15B, the gate electrode layers 276 may comprise any number of work function tuning layers and a fill material. The gate electrode layers 276 may be formed by a conformal deposition process such as, for example, ALD or CVD.

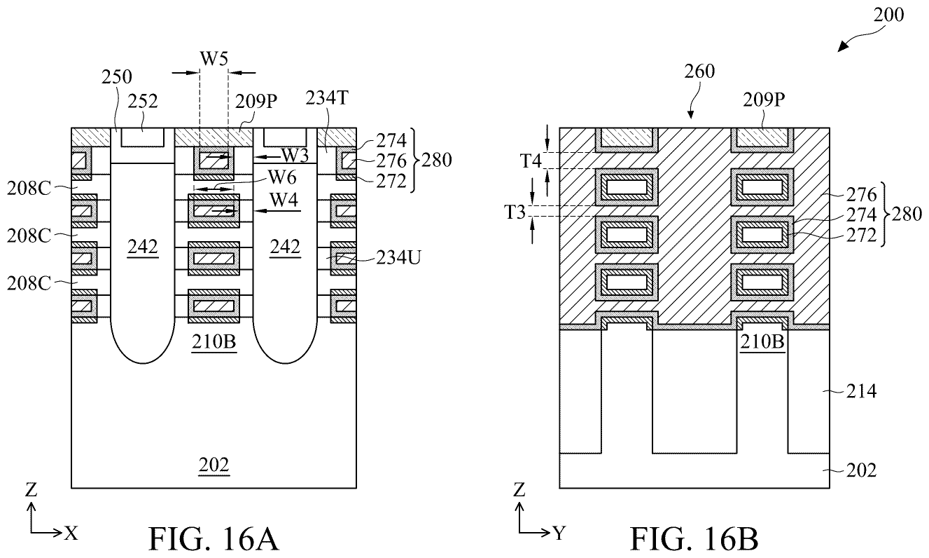

Referring to FIGS. 1 and 16A-16B, the method 100 proceeds to operation 130, where gate stacks 280 are formed in the gate trenches 260 and the gate gaps 262T, 262U, in accordance with some embodiments. FIGS. 16A and 16B are cross-sectional views of the GAA device 200 after forming the gate stacks 280.

Each gate stack 280 is formed to wrap around the channel nanostructures 208C within a fin structure 210. In some embodiments, a gate stack 280 includes interfacial layers 272 on the top, bottom, and sidewall surfaces of the channel nanostructures 208C, as well as on the top and sidewall surfaces of the base portions 210B; gate dielectric layers 274 on the interfacial layers 272 and on sidewall and bottom surfaces of the hard mask portion 209P; and a gate electrode layer 276 on the gate dielectric layers 274 to fill remaining volumes of the gate trench 260 and the gate gaps 262T, 262U. In some embodiments and as shown in FIG. 16B, the top surface of each gate stack 280 is coplanar with the top surfaces of the hard mask portions 209P.

To form the gate stacks 280, following deposition of the gate electrode layers 276, a planarization process, such as a CMP, may be performed to remove portions of the gate electrode layers 276 and the gate dielectric layers 274 from above the hard mask portions 209P, thereby exposing the top surfaces of the hard mask portions 209P. The interfacial layers 272, together with the remaining portions of the gate dielectric layers 274 and gate electrode layers 276, constitute replacement gates of the resulting nanosheet FETs. The planarization process also levels the gate spacers 226, contact etch stop layer 250, and ILD layer 252 with the hard mask portions 209P such that top surfaces of the remaining portions of the gate spacers 226, contact etch stop layer 250, and ILD layer 252 are coplanar with the top surfaces of the hard mask portions 209P.

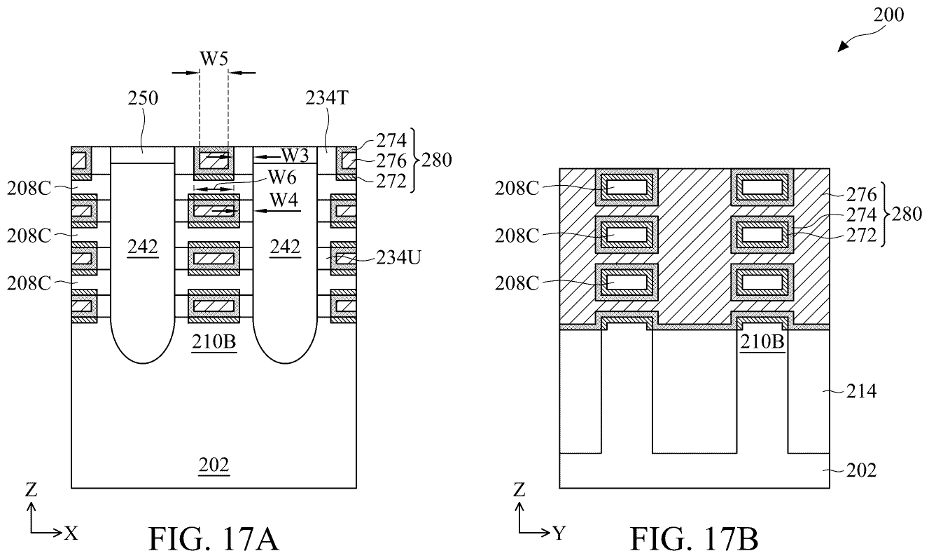

FIGS. 17A and 17B illustrate a GAA device 200 in accordance with a second exemplary embodiment, in which the planarization process is performed to completely remove the hard mask portions 209P from the structure. As a result, and as shown in FIGS. 17A and 17B, the gate dielectric layers 274 on the top surfaces of the topmost channel nanostructures 208C become exposed after planarization. In some embodiments, the planarization process also completely removes the ILD layer 252 overlying the source/drain features 242. In some embodiments, the planarization process removes a portion of the gate dielectric layer 274 over the top surface of the topmost channel nanostructure 208C. As a result, the thickness of the portion of the gate dielectric layer 274 over the top surface of the topmost channel nanostructure 208C is less than the thickness of the portions of gate dielectric layer 274 on the sidewall and bottom surfaces of the topmost channel nanostructures 208C.

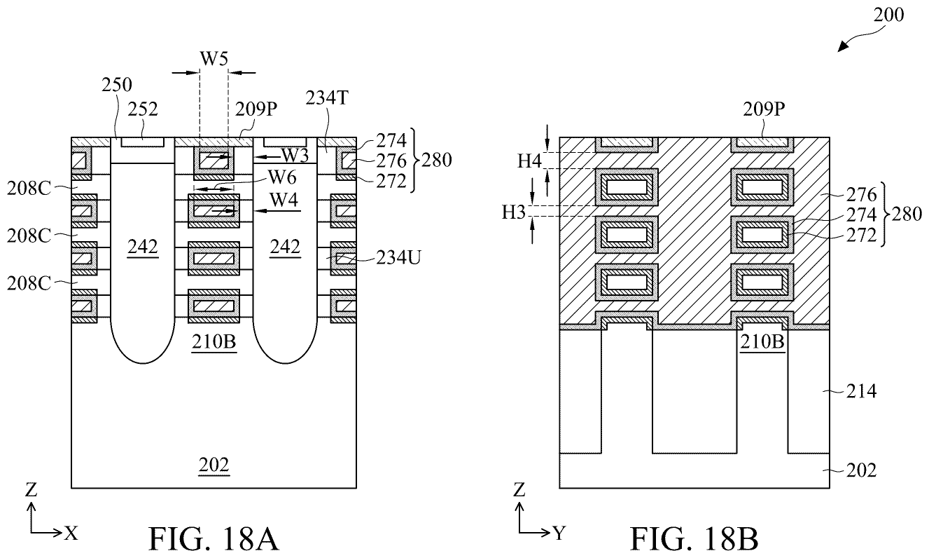

FIGS. 18A and 18B illustrate a GAA device 200 in accordance with a third exemplary embodiment, in which the planarization process is performed to partially remove the hard mask portions 209P from the structure. As a result, and as shown in FIGS. 18A and 18B, the gate stack 280 remains protected by the hard mask portions 209P, although with a reduced thickness compared to the hard mask portions 209P shown in FIGS. 16A and 16B.

As shown in FIGS. 16A-18B, within a fin structure 210, each of the gate stacks 280 thus formed includes a first portion located in the first gate gap 262T (i.e., the topmost gate gap) and second portions located in the second gate gaps 262U positioned below the first gate gap 262T. The first portion has a smaller width but a greater height compared to the second portions. In some embodiments, the width W5 of the first portion is about 0.5 nm to about 5 nm less than the width W6 of the second portions, while the height of the first portion is about 0.5 nm to about 2 nm greater than the height of the second portions. Further shown in FIGS. 16A, 17A, and 18A, the first portion is separated from the source/drain features 242 by a first inner spacer 234T having a width W3, whereas the second portions are separated from the source/drain features 242 by respective second inner spacers 234U, each having a width W4 that is less than W3. Accordingly, the first portion is spaced further from the source/drain features 242 than the second portions.

In embodiments of the present disclosure, by employing a thicker topmost sacrificial layer to form a metal gate stack with a top portion having a width smaller than the lower portions, and being spaced farther from the source/drain features, the effective capacitance (Ceff) can be reduced.

Additional processing may be performed to finish the fabrication of the GAA device 200. For example, gate and source/drain contacts (not illustrated for simplicity) may be formed to electrically couple to the gate stacks 280 and the source/drain features 242, respectively. An interconnect structure may then be formed over the source/drain contacts and the gate contacts. The interconnect structure may include a plurality of dielectric layers surrounding metallic features, including conductive traces and conductive vias, which form electrical connection between devices on the substrate 202, such as the GAA device 200.

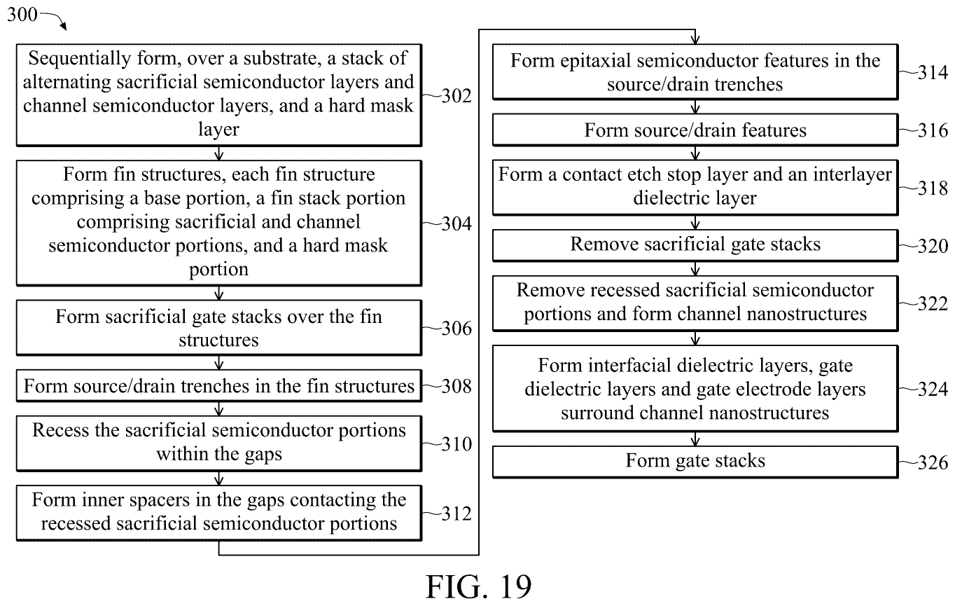

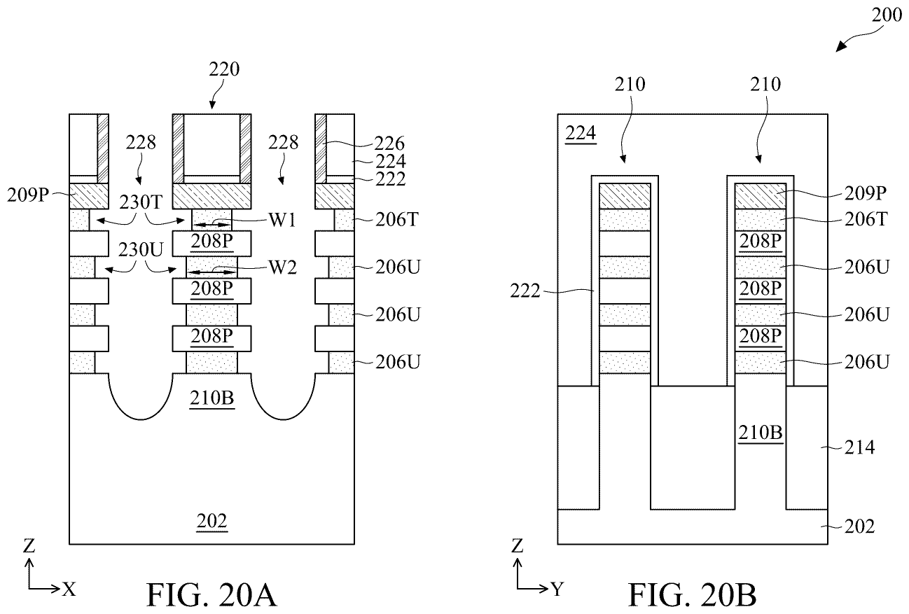

FIG. 19 is a flowchart of a method 300 of forming the GAA device 200, in accordance with alternative embodiments of the present disclosure. FIGS. 20A-26B are cross-sectional views of intermediate stages in the formation of the GAA device 200 corresponding to the method 300. Unless specified otherwise, the materials and the formation methods of the components in these embodiments are essentially the same as their like components, which are denoted by like reference numerals in the embodiments shown in FIGS. 2-18B. Accordingly, details regarding the formation processes and the materials of the components shown in FIGS. 20A-26B are thus found in the discussion of the embodiments shown in FIGS. 2-18B.

In contrast to the method 100, in which operations are performed to replace the sacrificial semiconductor portions with sacrificial dielectric portions, in the method 300, these operations are omitted such that the channel nanostructures are formed by removing the sacrificial semiconductor portions from the structure.

The initial operations of the method 300 are the same to operations 102-108 of the method 100. Referring to FIG. 19, at operation 302, the method 300 forms the initial structure of the GAA device 200 that includes a substrate 202, a stack 204 of alternating epitaxial semiconductor layers over the substrate 202, and a hard mask layer 209 over the stack 204, as previously described with respect to FIG. 2. At operation 304, the method 300 forms the fin structures 210 are formed from the stack 204 and a portion of the substrate 202, as previously described with respect to FIGS. 3A and 3B. At operation 306, the method 300 forms the sacrificial gate structures 220 over the fin structures 210, as previously described with respect to FIGS. 4A and 4B. At operation 308, the method 300 forms the source/drain trenches 228 in the fin structures 210, as previously described with respect to FIGS. 5A and 5B.

Referring to FIGS. 19 and 20A-20B, the method proceeds to operation 310, where the sacrificial semiconductor portions 206P are recessed, in accordance with some embodiments. FIGS. 20A and 20B are cross-sectional views of the GAA device 200 after recessing the sacrificial semiconductor portions 206P.

An etching process, for example, an isotropic etching process, may be performed to recess portions of the sacrificial semiconductor portions 206P exposed by the source/drain trenches 228, thereby forming the first recessed sacrificial semiconductor portions 206T within the first gaps 230T and the second recessed sacrificial semiconductor portions 206U within the second gaps 230U. Within each fin structure 210, the first recessed sacrificial semiconductor portion 206T is the topmost portion, positioned above the second recessed sacrificial semiconductor portions 206U. In embodiments of the present disclosure, the topmost sacrificial semiconductor portion 206TP is etched faster than the underlying sacrificial semiconductor portions 206P, because the topmost sacrificial semiconductor portion 206TP is either formed of a material having a higher etching rate, formed with a greater thickness, or both, compared to the underlying sacrificial semiconductor portions 206P. As shown in FIG. 20A, the width W1 of the first recessed sacrificial semiconductor portion 206T is less than the width W2 of the second recessed sacrificial semiconductor portions 206U. In some embodiments, the etching process is controlled such that the sidewalls of the second recessed sacrificial semiconductor portions 206U are aligned with the inner sidewall of the gate spacers 226, while the sidewalls of the first recessed sacrificial semiconductor portion 206T are recessed inward from the inner sidewalls of the gate spacers 226. In some embodiments, the second recessed sacrificial semiconductor portions 206U have substantially the same width.

The etching process selectively removes the material of the sacrificial semiconductor portions 206P without substantially etching the channel semiconductor portions 208P and the substrate 202. In some embodiments, when the channel semiconductor portions 208P include Si and the sacrificial semiconductor portions 206P include SiGe, the sacrificial semiconductor portions 206P may be recessed by applying an HCl gas at a temperature of about 500° C. to about 700° C., or applying a gas mixture of CF₄, SF₆, and CHF₃. In some other embodiments, the etching process may include oxidizing portions of the sacrificial semiconductor portions 206P using a suitable oxidizer, such as ozone. Thereafter, the oxidized portions of the sacrificial semiconductor portions 206P may be selectively removed.

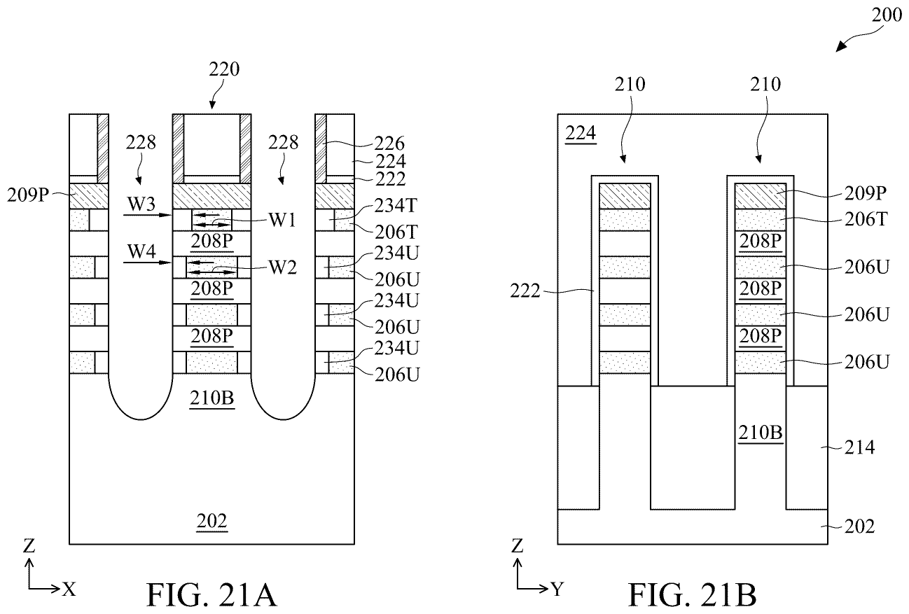

Referring to FIGS. 19 and 21A-21B, the method 300 proceeds to operation 312, where the first inner spacers 234T are formed in the first gaps 230T and the second inner spacers 234U are formed in the second gaps 230U, in accordance with some embodiments. FIGS. 21A and 21B are cross-sectional views of the GAA device 200 after forming the first inner spacers 234T and the second inner spacers 234U. The first inner spacers 234T contact sidewalls of the first recessed sacrificial semiconductor portions 206T, and the second inner spacers 234U contacts sidewalls of the second recessed sacrificial semiconductor portions 206U. The processes described above with respect to FIGS. 9A and 9B are performed to form the first inner spacers 234T and the second inner spacers 234U.

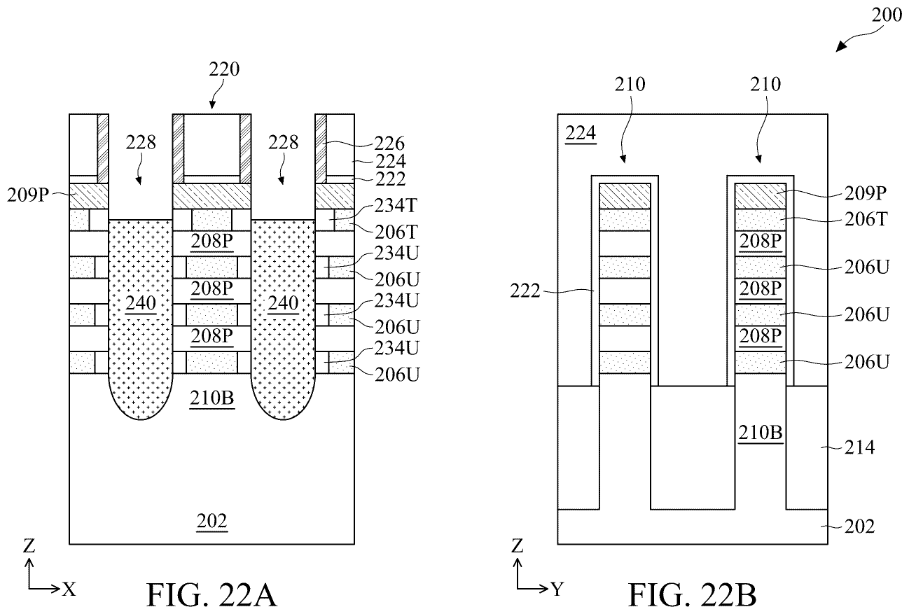

Referring to FIGS. 19 and 22A-22B, the method 300 proceeds to operation 314, where the epitaxial semiconductor features 240 are formed in the source/drain trenches 228, in accordance with some embodiments. FIGS. 22A and 22B are cross-sectional views of the GAA device 200 after forming the epitaxial semiconductor features 240 in the source/drain trenches 228. The processes described above with respect to FIGS. 10A and 10B are performed to form the epitaxial semiconductor features 240 in the source/drain trenches 228.

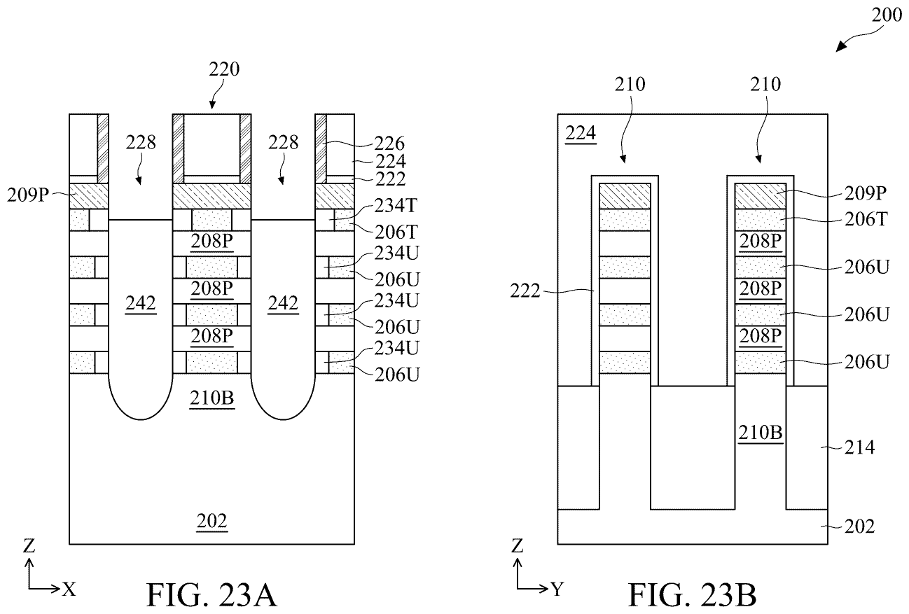

Referring to FIGS. 19 and 23A-23B, the method 300 proceeds to operation 316, where the dopants are implanted into the epitaxial semiconductor features 240 to form the source/drain features 242, in accordance with some embodiments. FIGS. 23A and 23B are cross-sectional views of the GAA device 200 after forming the source/drain features 242. The processes described above with respect to FIGS. 11A and 11B are performed to form the source/drain features 242.

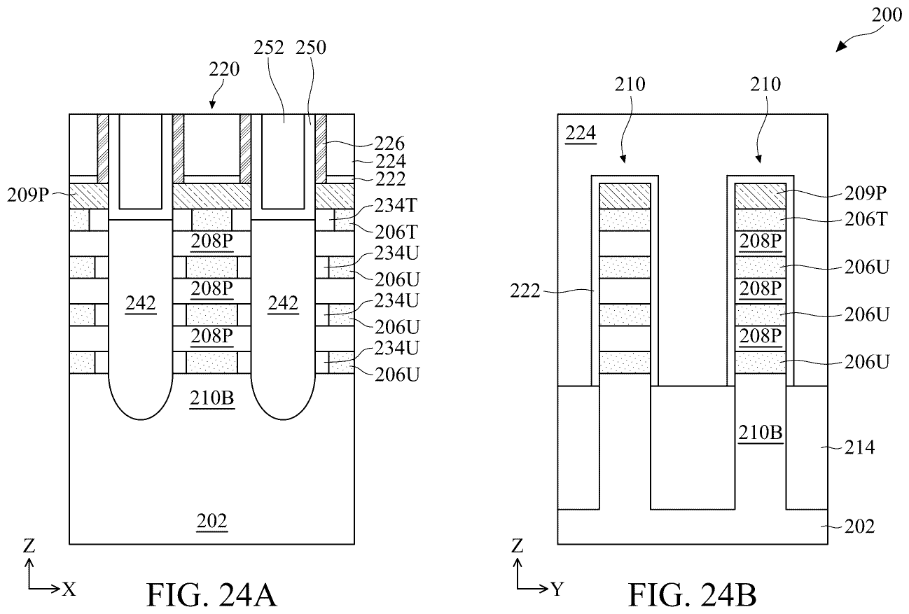

Referring to FIGS. 19 and 24A-24B, the method 300 proceeds to operation 318, where the contact etch stop layer (CESL) 250 is formed over the source/drain features 242, followed by forming the interlayer dielectric (ILD) layer 252 over the contact etch stop layer 250, in accordance with some embodiments. FIGS. 24A and 24B are cross-sectional views of the GAA device 200 after forming the contact etch stop layer 250 and the ILD layer 252. The processes described above with respect to FIGS. 12A and 12B are performed to form the contact etch stop layer 250 and the ILD layer 252.

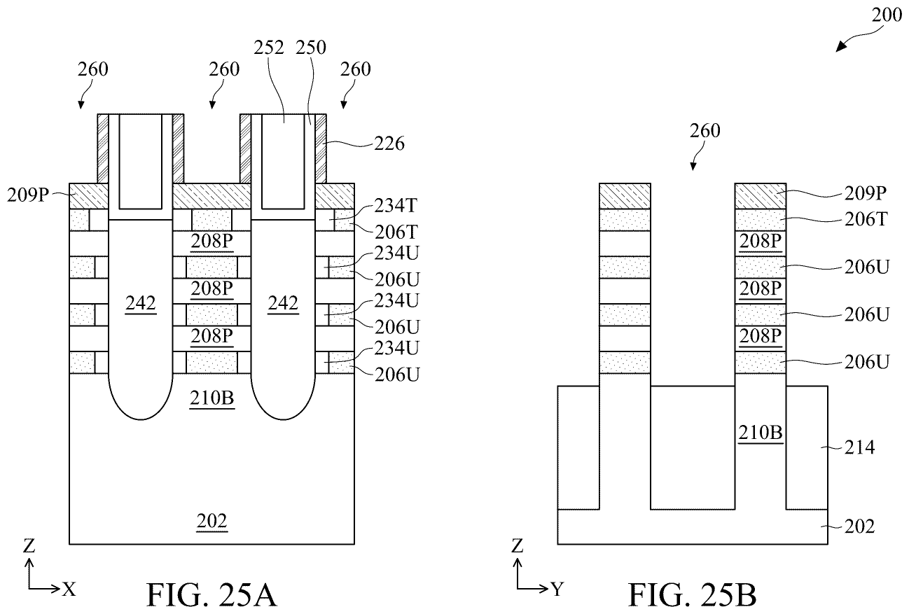

Referring to FIGS. 19 and 25A-25B, the method 300 proceeds to operation 320, where the sacrificial gate stacks (222, 224) are removed to form the gate trenches 260, in accordance with some embodiments. FIGS. 25A and 25B are cross-sectional views of the GAA device 200 after removing the sacrificial gate stacks (222, 224) to form the gate trenches 260.

The processes described above with respect to FIGS. 13A and 13B are performed to remove the sacrificial gate stacks (222, 224).

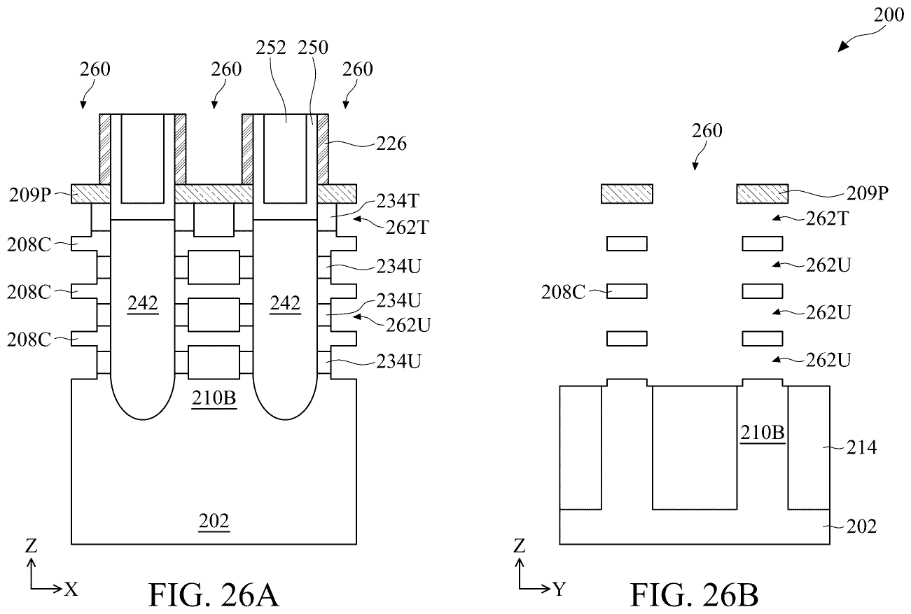

Referring to FIGS. 19 and 26A-26B, the method 300 proceeds to operation 322, where the recessed sacrificial semiconductor portions 206T, 206U ae removed, in accordance with some embodiments. FIGS. 26A and 26B are cross-sectional views of the GAA device 200 after removing the recessed sacrificial semiconductor portions 206T, 206U.

The selective removal of the recessed sacrificial semiconductor portions 206T, 206U releases the channel semiconductor portions 208P to form channel nanostructures 208C. In some embodiments, the recessed sacrificial semiconductor portions 206T, 206U may be removed by a selective etching process using an etchant that is selective to the material of recessed sacrificial semiconductor portions 206T, 206U, such that the recessed sacrificial semiconductor portions 206T, 206U are removed without substantially attacking the channel semiconductor portions 208P. In some embodiments, the etching process is an isotropic etching process which can be a dry etching process or a wet etching process. In some embodiments, the selective etching process may include oxidizing the recessed sacrificial semiconductor portions 206T, 206U using a suitable oxidizer, such as ozone. Thereafter, the oxidized recessed sacrificial semiconductor portions 206T and 206U may be selectively removed. In some embodiments, when the channel semiconductor portions 208P include Si and the recessed sacrificial semiconductor portions 206T, 206U include SiGe, the recessed sacrificial semiconductor portions 206T, 206U may be selectively removed by applying an HCl gas at a temperature of about 500° C. to about 700° C., or applying a gas mixture of CF₄, SF₆, and CHF₃.

Referring to FIG. 19, the method 300 proceeds to operation 324, where the interfacial layers 272, gate dielectric layers 274, and gate electrode layers 276 are formed for replacement gates, in accordance with some embodiments. The processes described above with respect to FIGS. 15A and 15B are performed to form the interfacial layers 272, gate dielectric layers 274, and gate electrode layers 276.

Referring to FIG. 19, the method 300 proceeds to operation 326, where the gate stacks 280 are formed in the gate trenches 260 and the gate gaps 262T, 262U, in accordance with some embodiments. The processes described above with respect to FIGS. 16A and 16B are performed to form the gate stacks 280.

One aspect of this description relates to a method for forming a semiconductor device. The method includes forming a fin structure extending along a first direction over a substrate, the fin structure having a height along a second direction transverse the first direction and including a stack portion of alternating channel semiconductor portions and sacrificial material portions, and a hard mask portion over the stack portion. The sacrificial material portions include a first sacrificial material portion in contact with the hard mask portion and second sacrificial material portions below the first sacrificial material portion. Next, the first sacrificial material portion and the second sacrificial material portions are laterally recessed. The first sacrificial material portion is etched to a greater extent than the second sacrificial material portions. After removing the recessed first sacrificial material portion and the recessed second sacrificial material portions to form a plurality of channel nanostructures from the channel semiconductor portions, a gate stack is formed to surround the channel nanostructures.

Another aspect of this description relates to a method for forming a semiconductor device. The method includes forming a fin structure extending along a first direction over a substrate. The fin structure has a height along a second direction transverse the first direction and includes a stack portion of alternating channel semiconductor portions and sacrificial semiconductor portions, and a hard mask portion over the stack portion. The sacrificial semiconductor portions include a first sacrificial semiconductor portion in contact with the hard mask portion and second sacrificial semiconductor portions below the first sacrificial semiconductor portion, the first sacrificial semiconductor portion having a first etching rate to an etchant and the second sacrificial semiconductor portions having a second etching rate to the etchant lower than the first etching rate. The first sacrificial semiconductor portion and the second sacrificial semiconductor portions are laterally recessed. Next, the recessed first sacrificial semiconductor portion and the recessed second sacrificial semiconductor portions are replaced with a gate stack to surround the channel semiconductor portions.

Still another aspect of this description relates to a semiconductor device. The semiconductor device includes a plurality of nanostructures over a substrate and extending along a lengthwise direction, a gate stack surrounding each of the plurality of nanostructures, and a source/drain feature adjacent to the gate stack. The gate stack includes a first portion over a top surface of a topmost nanostructure of the plurality of nanostructures and second portions positioned between adjacent nanostructures of the plurality of nanostructures. The first portion has a first dimension in the lengthwise direction, and the second portions each have a second dimension in the lengthwise direction greater than the first dimension.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a semiconductor device, comprising:
forming a fin structure extending along a first direction over a substrate, the fin structure having a height along a second direction transverse the first direction and comprising a stack portion comprising alternating channel semiconductor portions and sacrificial material portions, and a hard mask portion over the stack portion, wherein the sacrificial material portions include a first sacrificial material portion in contact with the hard mask portion and second sacrificial material portions below the first sacrificial material portion;
laterally recessing the first sacrificial material portion and the second sacrificial material portions, wherein the first sacrificial material portion is etched to a greater extent than the second sacrificial material portions;
removing the recessed first sacrificial material portion and the recessed second sacrificial material portions to form a plurality of channel nanostructures from the channel semiconductor portions; and
forming a gate stack surrounding the channel nanostructures.

2. The method of claim 1, wherein the channel semiconductor portions comprise a first semiconductor material, and the sacrificial material portions comprise a second semiconductor material different from the first semiconductor material.

3. The method of claim 1, wherein the first sacrificial material portion and the second sacrificial material portions are semiconductor portions of different compositions, wherein the first sacrificial material portion has a first etching rate to an etchant and the second sacrificial material portions have a second etching rate to the etchant less than the first etching rate.

4. The method of claim 1, wherein the first sacrificial material portion and the second sacrificial material portions are semiconductor portions of the same composition.

5. The method of claim 1, wherein the sacrificial material portions comprise a dielectric material, and the channel semiconductor portions comprise a semiconductor material.

6. The method of claim 1, wherein in the second direction, the first sacrificial material portion has a first thickness, and the second sacrificial material portions each have a second thickness less than the first thickness.

7. The method of claim 1, wherein in the first direction, the recessed first sacrificial material portion has a first width, and the recessed second sacrificial material portions each have a second width greater than the first width.

8. The method of claim 1, wherein forming the fin structure comprises:
forming, over the substrate, a stack of alternating sacrificial semiconductor layers and channel semiconductor layers with the sacrificial semiconductor layer being the topmost layer;
forming a hard mask layer over the stack; and
patterning the hard mask layer, the stack and a portion of the substrate.

9. The method of claim 8, further comprising forming a sacrificial gate structure over the fin structure, the sacrificial gate structure comprising a sacrificial gate electrode and gate spacers on sidewalls of the sacrificial gate electrode.

10. The method of claim 9, further comprising forming source/drain trenches in the fin structure on opposite sides of the sacrificial gate structure.

11. The method of claim 8, wherein patterning the stack forms alternating sacrificial semiconductor portions and the channel semiconductor portions, wherein the sacrificial semiconductor portions constitute the sacrificial material portions.

12. The method of claim 8, wherein patterning the stack forms alternating sacrificial semiconductor portions and the channel semiconductor portions, the method further comprising replacing the sacrificial semiconductor portions with sacrificial dielectric portions, forming the sacrificial material portions composed of a dielectric material.

13. The method of claim 1, further comprising forming inner spacers laterally surrounding the recessed first and second sacrificial material portions.

14. A method for forming a semiconductor device, comprising:
forming a fin structure extending along a first direction over a substrate, the fin structure having a height along a second direction transverse the first direction and comprising a stack portion comprising alternating channel semiconductor portions and sacrificial semiconductor portions, and a hard mask portion over the stack portion, wherein the sacrificial semiconductor portions include a first sacrificial semiconductor portion in contact with the hard mask portion and second sacrificial semiconductor portions below the first sacrificial semiconductor portion, the first sacrificial semiconductor portion having a first etching rate to an etchant and the second sacrificial semiconductor portions having a second etching rate to the etchant lower than the first etching rate;
laterally recessing the first sacrificial semiconductor portion and the second sacrificial semiconductor portion; and
replacing the recessed first sacrificial semiconductor portion and the recessed second sacrificial semiconductor portions with a gate stack to surround the channel semiconductor portions.

15. The method of claim 14, wherein in the first direction, the recessed first sacrificial semiconductor portion has a first width and the recessed second sacrificial semiconductor portions each have a second width greater than the first width.

16. The method of claim 14, wherein in the second direction, the first sacrificial semiconductor portion has a first thickness, and the second sacrificial semiconductor portions each have a second thickness less than the first thickness.

17. The method of claim 14, wherein the first sacrificial semiconductor portion comprises SiGe having a first Ge content, and the second sacrificial semiconductor portions comprise SiGe having a second Ge content less than the first Ge content.

18. The method of claim 14, wherein replacing the recessed first sacrificial semiconductor portion and the recessed second sacrificial semiconductor portions with the gate stack comprises:
forming inner spacers contacting sidewalls of the recessed first sacrificial semiconductor portion and the recessed second sacrificial semiconductor portions;
removing the recessed first sacrificial semiconductor portion and the recessed second sacrificial semiconductor portions to form gaps between the channel semiconductor portions and between a topmost channel semiconductor portion and the hard mask portion; and
forming the gate stack in the gaps.

19. A semiconductor device, comprising:
a plurality of nanostructures over a substrate and extending along a lengthwise direction;
a gate stack surrounding each of the plurality of nanostructures; and
a source/drain feature adjacent to the gate stack,
wherein the gate stack comprises a first portion over a top surface of a topmost nanostructure of the plurality of nanostructures and second portions positioned between adjacent nanostructures of the plurality of nanostructures, the first portion having a first dimension in the lengthwise direction, and the second portions each having a second dimension in the lengthwise direction greater than the first dimension.

20. The semiconductor device of claim 19, wherein the first portion of the gate stack comprises an interfacial layer over the top surface of the topmost nanostructure, a gate dielectric over the interfacial layer and a gate electrode over the interfacial layer surrounding the gate dielectric, wherein a portion of the gate dielectric over a top surface of the topmost nanostructure has a thickness less than portions of the gate dielectric on sidewall and bottom surfaces of the topmost nanostructure.
